(19) United States
(12) Patent Application Publication
(10) Pub. No.: US 2016/0181309 A1
(43) Pub. Date: Jun. 23, 2016

(54) MICROLENS AND METHOD OF MANUFACTURING MICROLENS

(71) Applicant: CANON KABUSHIKI KAISHA, Tokyo (JP)

(72) Inventor: Kosei Uehira, Tokyo (JP)

(21) Appl. No.: 14/955,435

(22) Filed: Dec. 1, 2015

(30) Foreign Application Priority Data
Dec. 22, 2014 (JP) 2014-258496
Jun. 4, 2015 (JP) 2015-113683

(51) Int. Cl. H01L 27/146

(52) U.S. Cl. CPC H01L 27/14685; H01L 27/14643; H01L 27/14689; H01L 27/14687; H01L 27/14627; H01L 27/14632; H01L 27/14607

(57) ABSTRACT

A method of manufacturing a microlens includes forming a first pattern over a substrate, forming a second pattern over the substrate with the first pattern formed on so as to cover the first pattern, a center of gravity of the second pattern being located at a position different from a position of a center of gravity of the first pattern in a plan view, and reflowing the second pattern to shape the second pattern and form a microlens.

### BACKGROUND OF THE INVENTION

1. Field of the Invention

The present invention relates to a microlens and a method of manufacturing microlens.

2. Description of the Related Art

Solid-state imaging devices, such as CCD image sensors and CMOS image sensors, are provided with on-chip microlenses over photoelectric conversion elements to increase the light collection efficiency of the photoelectric conversion elements.

Among various manufacturing methods of such microlenses that have been proposed, a reflow method, an etch-back method, and a method using a gray-tone mask are typical manufacturing methods based on a photolithographic technique. The reflow method is a method in which a photolithographically formed pattern is thermally fluidized through heat treatment to shape the pattern into a spherical shape and form a microlens.

The etch-back method is a method in which a lens shape is transferred by etching a base using a pattern of the lens shape, formed by the reflow method, as a mask, to form a microlens on the surface of the base. The method using a gray-tone mask is a method in which a gray-tone mask, with a pattern of dots smaller than a photolithographic resolution limit arranged therein, is used to form a spherical microlens by varying the degree of photoreaction of a photosensitive resin among regions.

Spherical microlenses manufactured by these methods have been hitherto widely used in solid-state imaging devices. However, as recent solid-state imaging devices have a larger number of pixels and larger imaging region, it has been increasingly difficult to obtain uniform photosensitivity in all the pixels in the imaging region by spherical microlenses. This is due to different focal positions of the microlenses in different locations in the imaging region, as light entering pixels in the center part of the imaging region enters from the vertical direction, while light entering pixels closer to the outer periphery enters from a direction inclined relative to the vertical direction.

From this viewpoint, a solid-state imaging device has been proposed in which microlenses having different shapes are disposed according to the location in the imaging region. For example, Japanese Patent Application Laid-Open No. 2006-215547 discloses a method in which a second lens pattern is formed on a part of a first lens pattern, and these lens patterns are simultaneously reflowed to form a microlens. The microlens formed by this method has a shape of which the curvature in a cross-section along a direction from the center of the imaging region toward the outside of the imaging region is asymmetrical. It is possible to correct the focal position of light entering from a direction inclined relative to the vertical direction and obtain uniform photosensitivity in the plane of the imaging region by increasing the degree of asymmetry of the curvature in the above cross-section of microlenses as the distance from the center of the imaging region increases.

However, to obtain a microlens of a desired shape by the method described in Japanese Patent Application Laid-Open No. 2006-215547, close adjustment of the melting points, heating conditions, viscosities upon liquefaction, etc. of the two lens patterns is required. Moreover, it is difficult to laminate the second lens pattern onto the thermally uncured first lens pattern, which makes it extremely difficult to control the lens shape.

On the other hand, a microlens having a shape as described in Japanese Patent Application Laid-Open No. 2006-215547 can also be formed by photolithography using a gray-tone mask as described in Japanese Patent Application Laid-Open No. 2004-145319 and Japanese Patent Application Laid-Open No. 2013-055161. However, it has been hitherto practically impossible to design dot patterns using a gray-tone mask that are suitable for individual microlenses of all pixels.

### SUMMARY OF THE INVENTION

An object of the present invention is to provide a microlens and a method of manufacturing a microlens which can easily realize a suitable lens shape corresponding to the incident direction of incident light.

According to one aspect of the present invention, there is provided a method of manufacturing a microlens including forming a first pattern over a substrate, forming a second pattern over the substrate with the first pattern formed on so as to cover the first pattern, a center of gravity of the second pattern being located at a position different from a position of a center of gravity of the first pattern in a plan view, and reflowing the second pattern to shape the second pattern and form a microlens.

According to another aspect of the present invention, there is provided a microlens provided over a substrate including a first part provided over the substrate, and a second part which is provided over the substrate so as to cover the first part, a center of gravity of the second part being located at a position different from a position of a center of gravity of the first part in a plan view, the second part having a rotationally asymmetrical shape with respect to an axis parallel to a normal direction of the substrate.

According to yet another aspect of the present invention, there is provided a solid-state imaging device including a substrate including an imaging region where a plurality of pixels including a photoelectric conversion element are arranged in a two-dimensional array, and a microlens array for collecting light on each of the photoelectric conversion element of the plurality of pixels, the microlens array being formed of a plurality of microlenses arranged in a two-dimensional array, each of the plurality of microlenses having a first part provided over the substrate, and a second part provided over the substrate so as to cover the first part, wherein a center of gravity of the second part is located at a position different from a position of a center of gravity of the first part in a plan view, and having a rotationally asymmetrical shape with respect to an axis parallel to a normal direction of the substrate, and the plurality of microlenses including at least two microlenses which are different from one another in distance between the position of the center of gravity of the first part and the position of the center of gravity of the second part in a plan view.

According to still another aspect of the present invention, there is provided a method of manufacturing a microlens array including forming a plurality of first patterns over a substrate, forming a plurality of second patterns over the substrate with the plurality of first patterns formed on so that each of the plurality of second patterns covers each of the plurality of first patterns, and reflowing the second patterns to shape the second patterns and form microlenses, wherein the plurality of first patterns has different shapes from one another.

Further features of the present invention will become apparent from the following description of exemplary embodiments with reference to the attached drawings.

### BRIEF DESCRIPTION OF THE DRAWINGS

FIG. 1A is a plan view illustrating the structure of a microlens according to a first embodiment of the present invention.

FIGS. 1B and 1C are cross-sectional views illustrating the structure of the microlens according to the first embodiment of the present invention.

FIGS. 2A and 2B are views illustrating the light collection capability of a spherical microlens.

FIGS. 3A and 3B are views illustrating the light collection capability of an aspherical microlens.

FIGS. 4A and 4B are views illustrating the light collection capability of an aspherical microlens.

FIGS. 5A, 5B, 5C, 5D, 5E and 5F are views illustrating a method of manufacturing the microlens according to the first embodiment of the present invention.

FIGS. 6A, 6B, 6C and 6D are plan views illustrating mask patterns for one pixel of a photomask used in embodiments of the present invention.

FIGS. 7A, 7B and 7C are views illustrating acting forces on a fluid and resulting changes in shape.

FIGS. 8A, 8B, 8C and 8D are views illustrating changes in shape of a pattern in the method of manufacturing the microlens according to the first embodiment of the present invention.

FIGS. 9A and 9B are views illustrating the light collection capability of the microlens according to the first embodiment of the present invention.

FIGS. 10A, 10B, 10C, 10D, 10E, 10F, 10G, 10H, 10I, 10J, 10K, 10L, 10M, 10N, 10O and 10P, FIGS. 11A, 11B, 11C and 11D and FIGS. 12A, 12B, 12C and 12D are views illustrating methods of manufacturing the microlens according to modified examples of the first embodiment of the present invention.

FIG. 13A is a cross-sectional view illustrating the structure of a microlens according to a second embodiment of the present invention.

FIGS. 13B and 13C are plan views illustrating the structure of the microlens according to the second embodiment of the present invention.

FIGS. 14A, 14B and 14C are views illustrating a method of manufacturing the microlens according to the second embodiment of the present invention.

FIGS. 15A, 15B and 15C are cross-sectional views illustrating a method of manufacturing the microlens according to third to fifth embodiments of the present invention.

FIG. 16 is a schematic cross-sectional view illustrating the structure of a solid-state imaging device according to a sixth embodiment of the present invention.

FIGS. 17A, 17B and 17C are cross-sectional views illustrating a method of manufacturing the microlens according to a seventh embodiment of the present invention.

FIG. 18 is a schematic cross-sectional view illustrating the structure of a solid-state imaging device according to an eighth embodiment of the present invention.

FIG. 19 is a schematic cross-sectional view illustrating the structure of a solid-state imaging device according to a ninth embodiment of the present invention.

FIG. 20A is a plan view illustrating the structure of a microlens according to a tenth embodiment of the present invention.

FIG. 20B is a cross-sectional view illustrating the structure of the microlens according to the tenth embodiment of the present invention.

FIGS. 21A, 21B and 21C are cross-sectional views illustrating a method of manufacturing the microlens according to the tenth embodiment of the present invention.

FIG. 22A is a plan view illustrating the structure of a microlens according to an eleventh embodiment of the present invention.

FIG. 22B is a cross-sectional view illustrating the structure of the microlens according to the eleventh embodiment of the present invention.

FIGS. 23A, 23B and 23C are cross-sectional views illustrating a method of manufacturing the microlens according to the eleventh embodiment of the present invention.

FIGS. 24A and 24B are views illustrating a microlens according to another embodiment of the present invention.

### DESCRIPTION OF THE EMBODIMENTS

Preferred embodiments of the present invention will now be described in detail in accordance with the accompanying drawings.

### First Embodiment

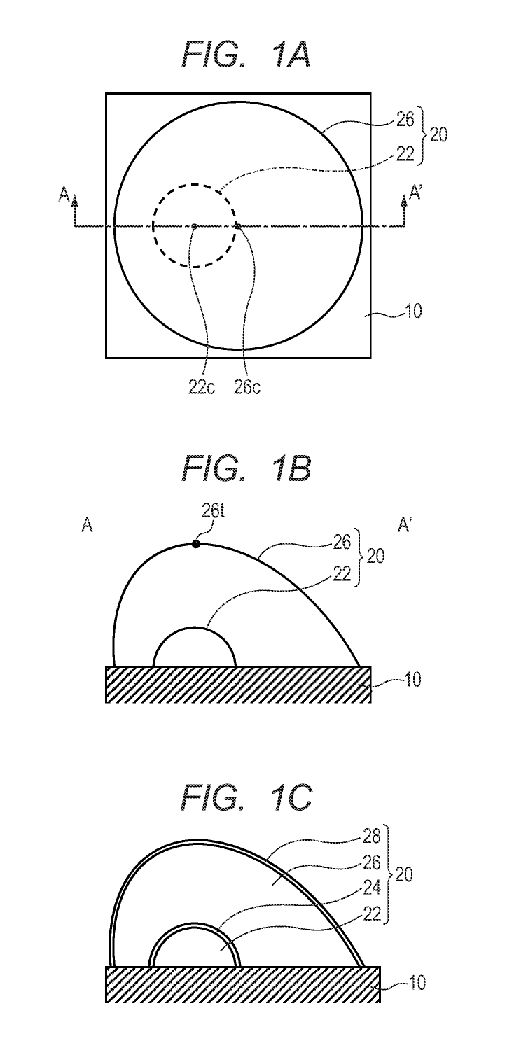

A microlens and a method of manufacturing the same according to a first embodiment of the present invention will be described using FIG. 1A to FIG. 12D.

First, the structure of the microlens according to the present embodiment will be described using FIG. 1A to FIG. 1C. FIG. 1A is a plan view illustrating the structure of the microlens according to the present embodiment, and FIG. 1B is a schematic cross-sectional view illustrating the structure of the microlens according to the present embodiment. FIG. 1C is a schematic cross-sectional view illustrating the structure of a microlens according to a modified example of the present embodiment.

As illustrated in FIG. 1A and FIG. 1B, a microlens 20 according to the present embodiment is an on-chip lens formed on a base substrate 10. The base substrate 10 is a substrate serving as a base on which the microlens 20 is to be formed, and the substrate is not particularly limited. For example, in the case of a microlens used for a solid-state imaging device, the base substrate 10 is a semiconductor substrate on which a photoelectric conversion element and its driving elements as well as interlayer insulating films covering these elements, etc. are formed. The microlens 20 in this case functions to collect light on the photoelectric conversion element.

The microlens 20 includes a first part 22 in contact with the base substrate 10, and a second part 26 in contact with the base substrate 10 while covering the first part 22. The first part 22 forms a convex portion on the surface of the base substrate 10. The second part 26 is formed so as to cover this convex portion formed by the first part 22. As illustrated in FIG. 1A, the first part 22 and the second part 26 have substantially circular shapes in a plan view. The position of a center of gravity 26c of the second part 26 in a plan view is offset from the position of a center of gravity 22c of the first part 22 in a plan view. As illustrated in FIG. 1B, the position of an apex 26t of the second part 26 in a cross-section is offset toward the position of the center of gravity 22c of the first part 22 in a plan view from the position of the center of gravity 26c of the second part 26 in a plan view. The amount of this offset is appropriately set according to the direction in which light enters the microlens 20 or to the position at which light is collected by the microlens 20.

Thus, the microlens 20 according to the present embodiment is an aspherical microlens. Here, an aspherical shape in this specification means that the shape is not rotationally symmetrical with respect to an axis parallel to the normal direction of the base substrate 10. A spherical shape means that the shape is rotationally symmetrical with respect to an axis parallel to the normal direction of the base substrate 10. The microlens 20 is plane-symmetrical in a cross-section including the line A-A′ and an axis parallel to the normal direction. The line A-A′ is assumed to extend along a direction from the center of an imaging region toward the outside in a microlens array.

For convenience of description, it is assumed that the microlens 20 includes the first part 22 and the second part 26 in the present embodiment. However, the first part 22 can also be regarded as a part of the base substrate 10. That is, it is also possible to consider that the microlens 20 having the second part 26 is formed on the base substrate 10 in which a protrusion is formed on the surface by the first part 22.

As illustrated in FIG. 1C, for example, the microlens 20 may be provided with an anti-reflection film 24 at the interface between the first part 22 and the second part 26, and an anti-reflection film 28 on the surface of the second part 26. Only one of the anti-reflection films 24 and 28 or both may be formed.

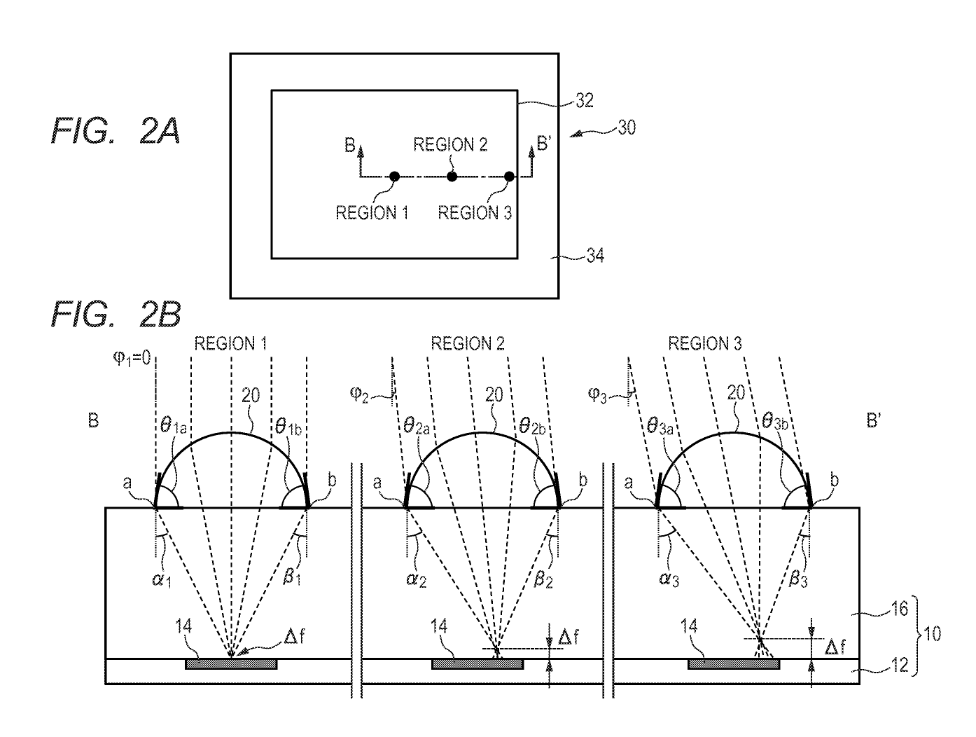

Next, the reason why the microlens 20 is given an aspherical shape in the present embodiment will be described using FIG. 2A to FIG. 4B, taking a case as an example where the microlens 20 is applied to a solid-state imaging device.

FIG. 2A and FIG. 2B are views illustrating the light collection capability of a spherical microlens. As illustrated in FIG. 2A, for example, a solid-state imaging device 30 includes an imaging region 32 where a plurality of pixels is arranged in a two-dimensional array, and a peripheral circuit region 34 which controls operation such as reading out pixel signals acquired in the imaging region 32. Here, the center part, the peripheral part and the region therebetween of the imaging region 32 are defined as a region 1, a region 3 and a region 2, respectively.

FIG. 2B is a schematic cross-sectional view illustrating pixels, extracted respectively from the region 1, the region 2 and the region 3, in a cross-section along the line B-B′ connecting the center part of the imaging region 32 and one point in the peripheral part of the imaging region 32 in FIG. 2A. The imaging region 32 is provided with a semiconductor substrate 12, on which a photodiode 14 being a photoelectric conversion element, a driving transistor (not illustrated), etc. are formed, an interlayer insulating film 16 disposed over the semiconductor substrate 12, and the microlens 20 disposed over the interlayer insulating film 16. The semiconductor substrate 12 and the interlayer insulating film 16 correspond to the above-described base substrate 10. The interlayer insulating film 16 may include a layer, such as a color filter, which is not colorless or transparent. The microlens 20 collects incident light (indicated by dashed lines in FIG. 2B) onto the photodiode 14. One microlens 20 is disposed in each pixel, and the microlenses 20 as a whole constitute a microlens array in which the plurality of microlenses 20 is arranged in a two-dimensional array.

A method using the technology called reflow method is known as a typical manufacturing method of the microlens 20. The reflow method is a method in which a photolithographically formed pattern is subjected to heat treatment to form a microlens. When a photolithographically formed pattern of a photosensitive resin material is subjected to heat treatment, solvent components of the pattern volatilize gradually, and when heated to a temperature above the melting point of 130° C. to 160° C., the pattern liquefies and deforms into a round lens shape. The pattern deforms into a lens shape because the balance among acting forces, such as the gravity, surface tension, and fluid friction force, becomes stable when the pattern assumes a spherical shape. If the pattern is continuously heated thereafter, resin components of the pattern cure and the pattern solidifies as is in the lens shape. Stopping heating and then cooling the pattern completes the microlens 20 having a spherical lens shape.

If a microlens array is formed by the reflow method, all the microlenses 20 have the same shape. For example, in the example illustrated in FIG. 2B, the microlens 20 formed in the region 1, the microlens 20 formed in the region 2, and the microlens 20 formed in the region 3 have the same shape. That is, contact angles θ of the microlenses 20 relative to the interlayer insulating film 16 are equal in value among all the microlenses 20. When the contact angles of the microlens 20 relative to the interlayer insulating film 16 at both ends in the illustrated cross-section are defined as θₙₐ, θ_{nb} (n is an integer corresponding to the regions 1 to 3) as illustrated in FIG. 2B, the following relation holds:

θ₁ₐ=θ_{1b}=θ₂ₐ=θ_{2b}=θ₃ₐ=θ_{3b}

Here, the contact angles θ₁ₐ, θ_{1b} are the contact angles of the microlens 20 of a pixel formed in the region 1. The contact angles θ₂ₐ, θ_{2b} are the contact angles of the microlens 20 of a pixel formed in the region 2. The contact angles θ₃ₐ, θ_{3b} are the contact angles of the microlens 20 of a pixel formed in the region 3. The contact angle θₙₐ is a contact angle at the end of the microlens on the center side of the imaging region 32 on the line B-B′, and the contact angle θ_{nb} is a contact angle at the opposite end (see FIG. 2B).

Light entering the imaging region 32 inclines from vertical incidence to oblique incidence as the distance from the center part (region 1) of the imaging region 32 increases. The smaller the F-number of an optical system of an imaging system which employs the solid-state imaging device 30 is, the larger the inclination of the oblique incident light.

Light entering the microlens 20 refracts according to Snell's law. That is, the relation between an incident angle θ_{A} and a refraction angle θ_{B} when light enters from a medium A having a reflective index n_{A} into a medium B having a refractive index n_{B} is expressed as follows:

n_{A}×sin θ_{A}=n_{B}×sin θ_{B} (1)

When light enters from the medium A which is air into the microlens 20 being the medium B, the left side of the equation (1) is a parameter on the air side, and the right side of the equation (1) is a parameter on the side of the microlens 20. When the refractive index of air is 1, the left side is represented by sin θ_{A}. The refractive index n_{B} varies depending on the material of the microlens.

In the region 1 where light enters vertically (incident angle φ₁=0 degrees), the refraction angles at the position a and the position b are equal. The contact angles θ₁ₐ, θ_{1b} of the microlens 20 are optimized according to the thickness of the interlayer insulating film 16 so as to achieve the best focus (Δf=0%). That is, the light collection capability is high in the region 1. For example, in the case where an optical system having an F-number of 2.8 is used, when the contact angles θ₁ₐ=θ_{1b}=60 degrees and the refractive index of the microlens 20 is 1.6, light entering vertically at an incident angle φ₁=0 degrees refracts off the microlens 20 and turns into light having inclination angles α₁=β₁=approximately 27 degrees. The inclination angle αₙ is an inclination angle relative to the vertical direction of refracted light of the light entering at the position a, and the inclination angle βₙ is an inclination angle relative to the vertical direction of refracted light of the light entering at the position b (n is an integer corresponding to the regions 1 to 3). The symbol Δf represents the ratio of the focal height of the microlens 20, with reference to the surface of the semiconductor substrate 12, to the film thickness of the interlayer insulating film 16. That is, the smaller the value of Δf is, the closer the focal position is to the semiconductor substrate 12.

The contact angles θ₂ₐ, θ_{2b} of the microlens 20 in the region 2 are the same as the contact angles θ₁ₐ, θ_{1b} of the microlens 20 in the region 1. However, unlike in the region 1, light enters obliquely in the region 2, so that the refraction angle is different from that of the region 1. By comparison, the inclination angle of light refracting at the position a is larger than that of the region 1, while the inclination angle of light refracting at the position b is smaller than that of the region 1. For example, light entering obliquely at an incident angle θ₂=5 degrees refracts off the microlens 20 and turns into light having an inclination angle α₂=approximately 29 degrees and an inclination angle β₂=approximately 25 degrees. Compared with the light in the region 1, the light in the region 2 is inclined by 2 degrees at both positions and has different light path lengths inside the interlayer insulating film 16, thus the focal position in the region 2 is higher. As a result, the lens focus deviation rate Δf is 0.6%.

The deviation rate is even higher in the region 3. For example, light entering obliquely at an incident angle φ₃=10 degrees refracts off the microlens 20 and turns into light having an inclination angle α₃=approximately 31 degrees and an inclination angle β₃=approximately 24 degrees. The focal position is even higher than that of the region 2. As a result, the lens focus deviation rate Δf is 2.6%.

The same tendency as described above can be seen, to varying degrees, with different F-numbers of the optical system as well. Table 1 shows calculation results in the case where the F-number is 16.0 and the case where the F-number is 1.4, along with calculation results in the above-described case where the F-number is 2.8.

TABLE 1

| | | Lens | | | | | | |
|---|---|---|---|---|---|---|---|---|
| | | Refractive | | | | | | |
| F-number | Region n | Index | θₙₐ | θ_{nb} | φₙ | αₙ | βₙ | Δf |
| 16.0 | 1 | 1.60 | 60 | 60 | 0 | 27 | 27 | 0.0% |
| | 2 | 1.60 | 60 | 60 | 1 | 28 | 27 | 0.0% |
| | 3 | 1.60 | 60 | 60 | 2 | 28 | 27 | 0.1% |
| 2.8 | 1 | 1.60 | 60 | 60 | 0 | 27 | 27 | 0.0% |
| | 2 | 1.60 | 60 | 60 | 5 | 29 | 25 | 0.6% |
| | 3 | 1.60 | 60 | 60 | 10 | 31 | 24 | 2.6% |
| 1.4 | 1 | 1.60 | 60 | 60 | 0 | 27 | 27 | 0.0% |
| | 2 | 1.60 | 60 | 60 | 10 | 31 | 24 | 2.6% |
| | 3 | 1.60 | 60 | 60 | 20 | 36 | 22 | 9.7% |

Thus, when a microlens array has spherical microlenses 20 all having the same shape, it is not possible to respond to oblique incident light which varies with the distance from the center of the imaging region 32, so that the lens focus deviation rate Δf becomes higher toward the outer peripheral side of the imaging region 32. As the light collection capability deteriorates in the peripheral part having a higher lens focus deviation rate Δf, the sensitivity deteriorates in the peripheral region.

To respond to oblique incident light, of which the incident direction varies with the distance from the center of the imaging region 32, it is conceivable to adjust the shape of the microlens 20 of each pixel according to the position in the imaging region 32.

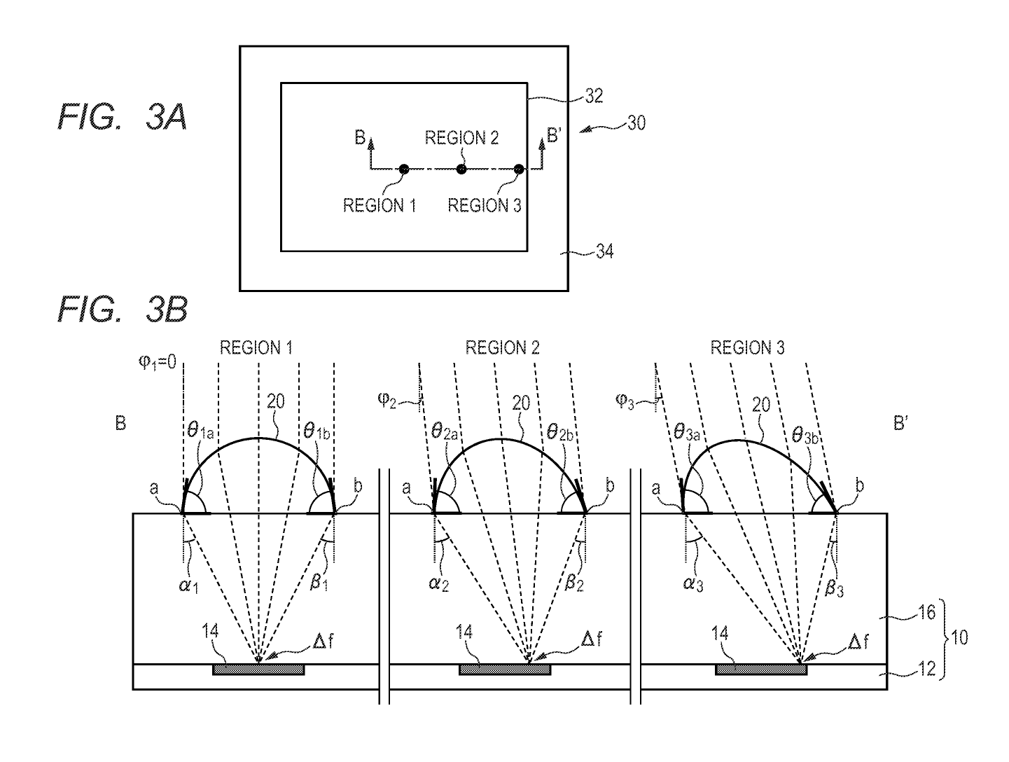

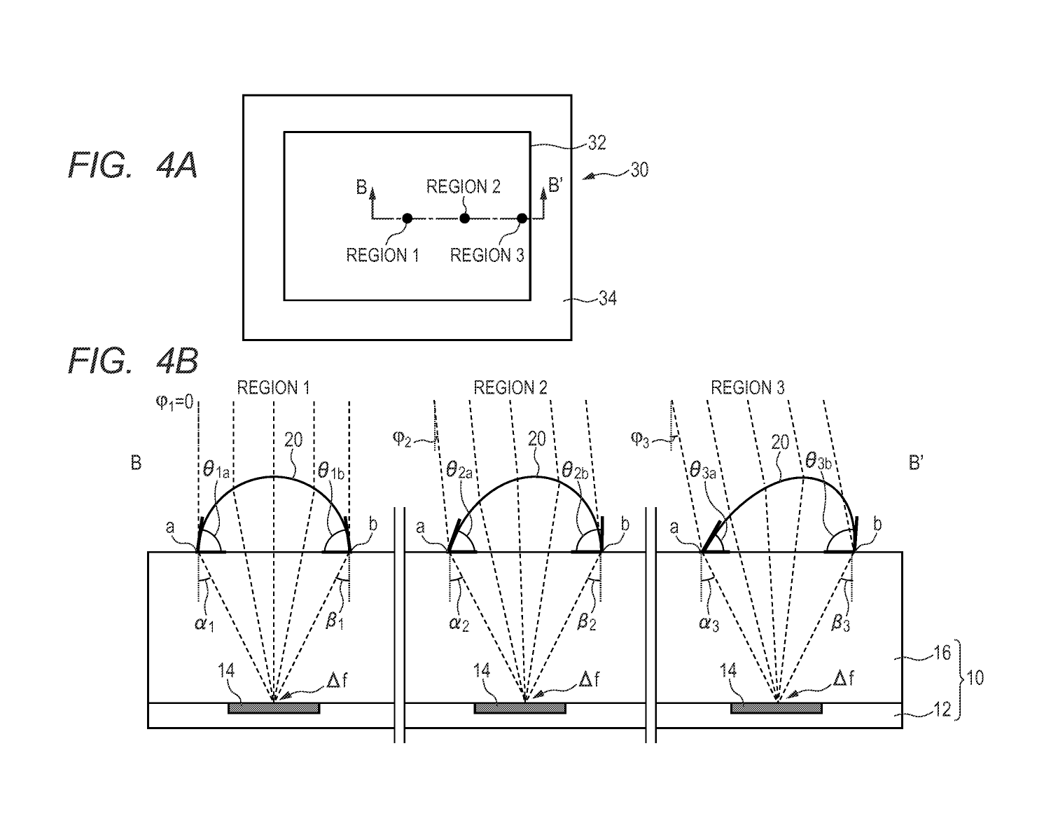

FIG. 3A to FIG. 4B are views illustrating the light collection capability of an aspherical microlens. FIG. 3A and FIG. 3B are one example in which the shape of the microlens 20 is varied according to the position in the imaging region 32. FIG. 3A is a top view of the solid-state imaging device. FIG. 3B is a schematic cross-sectional view illustrating pixels, extracted respectively from the region 1, the region 2 and the region 3, in a cross-section along the line B-B′ of FIG. 3A.

The microlens array of the solid-state imaging device 30 illustrated in FIG. 3A and FIG. 3B includes a plurality of types of microlenses 20 having different shapes from one another. The microlenses 20 disposed in parts (region 2 and region 3) away from the center part (region 1) of the imaging region 32 have rotationally asymmetrical shapes with respect to the center of gravity, and the center of gravity and the center of the pixel do not coincide with each other. The surfaces of these microlenses 20 are not spherical, but are kind of ellipsoidal. In this specification, the microlens 20 of such a shape is defined as an aspherical microlens.

In the microlens array of FIG. 3B, the microlenses 20 of the pixels farther away from the center of the imaging region have a larger amount of shift, toward the center of the imaging region 32, of the position of the center of gravity of the microlens 20 relative to the center of the pixel. This relation is expressed as follows in terms of the contact angles of the microlens 20, with the contact angle of the microlens on the center side of the imaging region 32 being θₙₐ and the contact angle on the opposite side being θ_{nb}:θ₁ₐ=θ_{1b} in the region 1, θ₂ₐ>θ_{2b} in the region 2, and θ₃ₐ>>θ_{3b} in the region 3. Here, n is an integer corresponding to the regions 1 to 3.

Table 2 shows one example of calculation results of parameters in the cases where the F-number of the optical system is 16.0, 2.8 and 1.4 in the microlens array of FIG. 3B.

TABLE 2

| | | Lens | | | | | | |
|---|---|---|---|---|---|---|---|---|
| | | Refractive | | | | | | |
| F-number | Region n | Index | θₙₐ | θ_{nb} | φₙ | αₙ | βₙ | Δf |
| 16.0 | 1 | 1.60 | 60 | 60 | 0 | 27 | 27 | 0.0% |
| | 2 | 1.60 | 65 | 54 | 1 | 31 | 23 | −0.1% |
| | 3 | 1.60 | 70 | 46 | 2 | 35 | 18 | −0.4% |
| 2.8 | 1 | 1.60 | 60 | 60 | 0 | 27 | 27 | 0.0% |
| | 2 | 1.60 | 65 | 54 | 5 | 32 | 22 | 0.0% |
| | 3 | 1.60 | 70 | 46 | 10 | 37 | 15 | 0.0% |
| 1.4 | 1 | 1.60 | 60 | 60 | 0 | 27 | 27 | 0.0% |
| | 2 | 1.60 | 65 | 54 | 10 | 34 | 20 | 1.3% |
| | 3 | 1.60 | 70 | 46 | 20 | 41 | 11 | 5.1% |

Of the calculation examples of Table 2, the case where the F-number of the optical system is 2.8 will be described as an example. The refractive index of the microlens is assumed to be 1.60.

In the region 1, a spherical microlens 20 having contact angles θ₁ₐ=θ_{1b}=60 degrees is formed. Accordingly, light entering vertically at an incident angle φ₁=0 degrees refracts off the microlens 20 and turns into light having inclination angles α₁=β₁=approximately 27 degrees.

In the region 2, an aspherical microlens 20 having contact angles θ₂ₐ=65 degrees and θ_{2b}=54 degrees is formed. For example, light entering obliquely at an incident angle θ₂=5 degrees refracts off the microlens 20 and turns into light having an inclination angle α₂=approximately 32 degrees and an inclination angle β₂=approximately 22 degrees. Compared with the inclination angles α₁=β₁=approximately 27 degrees of the region 1, both inclination angles are inclined by 5 degrees, while the focal plane is almost the same as in the region 1 (Δf=0%). Therefore, light collection capability equivalent to that of the region 1 can be maintained.

In the region 3, a microlens 20 having contact angles θ₃ₐ=70 degrees and θ_{3b}=46 degrees is formed. For example, light entering obliquely at an incident angle φ₃=10 degrees refracts off the microlens 20 and turns into light having an inclination angle α₃=approximately 37 degrees and an inclination angle β₃=approximately 15 degrees. Compared with the inclination angles of the region 1, the inclination angles are inclined by 10 degrees and 12 degrees, respectively, while the focal plane is almost the same as in the region 1 (Δf=0%). Therefore, light collection capability equivalent to that of the region 1 can be maintained.

FIG. 4A and FIG. 4B are another example in which the shape of the microlens 20 is varied according to the position in the imaging region 32. FIG. 4A is a top view of the solid-state imaging device. FIG. 4B is a schematic cross-sectional view illustrating pixels, extracted respectively from the region 1, the region 2 and the region 3, in a cross-section along the line B-B′ of FIG. 4A.

In the microlens array of FIG. 4B, the microlenses 20 of the pixels farther away from the center of the imaging region 32 have a larger amount of shift, toward the outer periphery of the imaging region 32, of the position of the center of gravity of the microlens 20 relative to the center of the pixel. This relation is expressed as follows in terms of the contact angles of the microlens 20, with the contact angle of the microlens on the center side of the imaging region 32 being θₙₐ and the contact angle on the opposite side being θ_{nb}:θ₁ₐ=θ_{1b} in the region 1, θ₂ₐ<θ_{2b} in the region 2, and θ₃ₐ<<θ_{3b} in the region 3. Here, n is an integer corresponding to the regions 1 to 3.

Table 3 shows one example of calculation results of parameters in the cases where the F-number of the optical system is 16.0, 2.8 and 1.4 in the microlens array of FIG. 4B.

TABLE 3

| | | Lens | | | | | | |
|---|---|---|---|---|---|---|---|---|
| | | Refractive | | | | | | |
| F-number | Region n | Index | θₙₐ | θ_{nb} | φₙ | αₙ | βₙ | Δf |
| 16.0 | 1 | 1.60 | 60 | 60 | 0 | 27 | 27 | 0.0% |
| | 2 | 1.60 | 57 | 62 | 1 | 26 | 28 | −0.9% |
| | 3 | 1.60 | 52 | 64 | 2 | 24 | 29 | −3.6% |
| 2.8 | 1 | 1.60 | 60 | 60 | 0 | 27 | 27 | 0.0% |
| | 2 | 1.60 | 57 | 62 | 5 | 28 | 27 | 0.0% |
| | 3 | 1.60 | 52 | 64 | 10 | 27 | 27 | 0.0% |
| 1.4 | 1 | 1.60 | 60 | 60 | 0 | 27 | 27 | 0.0% |
| | 2 | 1.60 | 57 | 62 | 10 | 30 | 26 | 2.2% |
| | 3 | 1.60 | 52 | 64 | 20 | 33 | 26 | 8.2% |

Of the calculation examples of Table 3, the case where the F-number of the optical system is 2.8 will be described as an example. The refractive index of the microlens is assumed to be 1.60.

In the region 1, a microlens 20 having contact angles θ₁ₐ=θ_{1b}=60 degrees is formed. Accordingly, light entering vertically at an incident angle φ₁=0 degrees refracts off the microlens 20 and turns into light having inclination angles α₁=β₁=approximately 27 degrees.

In the region 2, an aspherical microlens 20 having a contact angle θ₂ₐ=57 degrees and a contact angle θ_{2b}=62 degrees is formed. For example, light entering obliquely at an incident angle φ₂=5 degrees refracts off the microlens 20 and turns into light having an inclination angle α₂=approximately 28 degrees and an inclination angle β₂=approximately 27 degrees. Since almost equivalent light is maintained as compared with the inclination angles α₁=β₁=approximately 27 degrees of the region 1, the focal plane in the region 2 is almost the same as in the region 1 (Δf=0%). Accordingly, light collection capability equivalent to that of the region 1 can be maintained.

In the region 3, an aspherical microlens 20 having a contact angle θ₃ₐ=52 degrees and θ_{3b}=64 degrees is formed. For example, light entering obliquely at an incident angle φ₃=10 degrees refracts off the microlens 20 and turns into light having an inclination angle α₃=approximately 27 degrees and an inclination angle β₃=approximately 27 degrees. Since almost equivalent light is maintained as compared with the region 1, the focal plane in the region 3 is almost the same as in the region 1 (Δf=0%). Accordingly, light collection capability equivalent to that of the region 1 can be maintained.

The structures illustrated in FIG. 3B and FIG. 4B have equivalent light collection capability, since both structures have the deviation rate Δf=0% when a lens having an F-number of 2.8 is used. Therefore, which of the microlens structures to select depends on what parameter is important other than the deviation rate Δf, i.e., on the purpose of the microlens.

For example, the deviation of the focal position of the microlens 20 from directly under the microlens 20 is smaller in the structure of FIG. 4B than in the structure of FIG. 3B. In the structure of FIG. 4B, the inclination angles are β₁≈β₂≈β₃≈27 degrees, and the light collection angles of the microlenses 20 on the outer peripheral side are equivalent. If the light angles on the β side are thus uniform in the figure, variation in amount of color mixture among pixels is small in the plane of the imaging region 32. This is because a part of oblique light is reflected by the surface of the photodiode 14 and enters an adjacent pixel. Therefore, when suppression of color mixture is given importance, the inclination angles β₁, β₂, β₃ can be similar as in the structure of FIG. 4B.

By contrast, the structure of FIG. 3B has a smaller variation in light collection capability dependent on the F-number of the optical system used in the imaging system. Actually, as can be seen by comparing the values shown in Tables 1 to 3, the value of Δf in the region 3 when an optical system having an F-number of 1.4 is used is most suitable in the structure illustrated in FIG. 3B. Therefore, if importance is given to the light collection capability less susceptible to variation of the F-number, the structure illustrated in FIG. 3B is suitable.

That is, which of the structures of FIG. 3B and FIG. 4B is more suitable depends on the purpose of the microlens.

Hereinafter, examples where the present invention is applied to the structure of FIG. 3B will be representatively described, although the present invention is applicable to the structure of FIG. 4B as well.

Two methods to be described below are examples of the method of manufacturing the aspherical microlens illustrated in FIG. 3B and FIG. 4B.

A first method is a method in which a second pattern is laminated on a first pattern and these patterns are simultaneously reflowed to form an aspherical microlens.

However, this first method requires close adjustment of the melting points, heating conditions, viscosities upon liquefaction, etc. of materials of the two patterns. Since typical photosensitive resin materials have melting points close to one another and low viscosities upon liquefaction, when liquefied, the two materials of the patterns get mixed and assume a spherical shape, so that no aspherical microlens can be formed. Moreover, it is difficult to laminate the second pattern on the first pattern which is thermally uncured and half-dry. If the first pattern is in a half-dry state, the first pattern is sensitized along with the second pattern through exposure and development during formation of the second pattern, which results in deformation. Other concerns in laminating the second pattern onto the half-dry first pattern include application unevenness. Thus, due to the difficulty of obtaining a desired shape, the first method is difficult to apply as an aspherical microlens manufacturing method.

A second method is a method in which an aspherical microlens is formed by photolithography using a gray-tone mask. This method is less difficult than the first method, since it involves simply disposing a dot pattern on a photomask so that the finished pattern assumes an aspherical shape. However, it is practically impossible to design dot patterns for all the pixels of a solid-state imaging device, which has 20 to 30 million pixels on average, when designing an asymmetrical microlens corresponding to oblique incident light. The pixel size is 1 micrometer to several micrometers on one side, while the minimum size of dots that can be formed by a mask drawing apparatus is approximately 50 nanometers on one side, and the number of dots that can be disposed in one microlens is 20 dots/side to several dozen dots/side. It is not possible to represent the shapes of 20 to 30 million pixels with the gradation which can be realized by several dozen dots on one side.

Therefore, to form a microlens array having aspherical microlenses by photolithography using a gray-tone mask, the design method of a gray-tone mask needs to be devised. For example, the imaging region 32 of the solid-state imaging device may be divided into several areas, and all the dot patterns in the areas may be designed based on the incident angle of representative incident light in each area.

However, since a microlens array divided into areas has a large amount of variation in light collection capability at the border between one area and another, images taken are highly likely to be afflicted with borders. While improvement for avoiding recognition of borders is of course conceivable, it is more desirable to form a microlens array substantially free of area division.

Thus, while the second method can easily form one aspherical microlens, area division is required to form a microlens array, which makes it difficult to obtain satisfactory image quality. To solve these problems with the first method and the second method, the microlens 20 is configured in the present embodiment which includes the first part 22 in contact with the base substrate 10 and the second part 26 in contact with the base substrate 10 while covering the first part 22. The position of the center of gravity 26c of the second part 26 in a plan view is offset from the position of the center of gravity 22c of the first part 22 in a plan view. Thus, the position of the apex 26t of the second part 26 in a cross-sectional view is offset toward the position of the center of gravity 22c of the first part 22 in a plan view from the position of the center of gravity 26c of the second part 26 in a plan view.

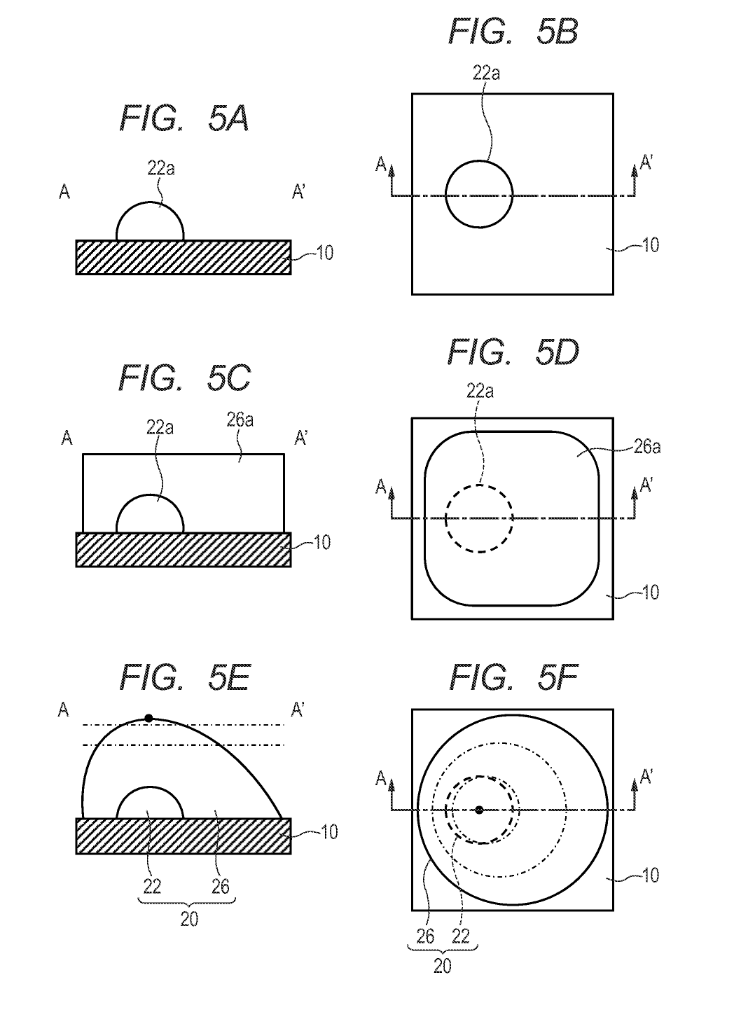

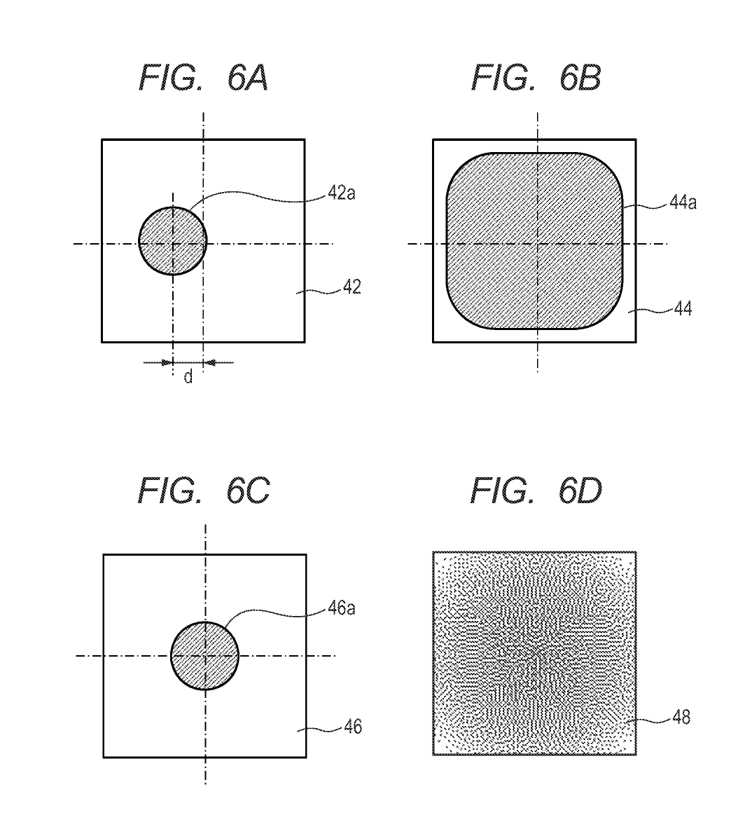

Next, using FIG. 5A to FIG. 6D, the reason why such a microlens 20 including the first part 22 and the second part 26 is configured in the present embodiment will be described along with a method of manufacturing the microlens 20 according to the present embodiment.

FIG. 5A to FIG. 5F are views illustrating the method of manufacturing the microlens according to the present embodiment. FIG. 6A to FIG. 6D are plan views illustrating mask patterns of one pixel of a photomask used in the present embodiment. First, a first pattern 22a is formed by photolithography, for example, on a first region of the base substrate 10 (FIG. 5A and FIG. 5B). For example, after a positive photosensitive resin film is formed on the base substrate 10, the photosensitive resin film is exposed and developed using a photomask having a mask pattern 42 illustrated in FIG. 6A, for example. In FIG. 6A to FIG. 6D, the lines surrounding each figure are an image of one pixel region, and the shaded region indicates a light shielding portion. In the mask pattern 42 illustrated in FIG. 6A, the center of a light shielding portion 42a corresponding to the formation region of the first pattern 22a is disposed so as to be offset by a distance d in one direction from the center of the pixel region. When the photosensitive resin film which has been patterned by development is subjected to heat treatment, the photosensitive resin softens and fluidizes, so that the film is shaped into a spherical shape due to surface tension. If heat treatment is continued thereafter, the photosensitive resin cures. Thus formed is the first pattern 22a.

Optionally, a negative photosensitive resin material may be used to form the first pattern 22a. It is not absolutely necessary to use photolithography to form the first pattern 22a. For example, the first pattern 22a may be formed by such a method as drips a resin material onto the base substrate 10 by, e.g., an inkjet method. The first pattern 22a and the base substrate 10 may have the same composition and be integrally formed. For example, the pattern of the first pattern 22a may be transferred to the surface of the base substrate 10 by etching-back the base substrate 10 using the first pattern 22a formed by the above-described method as a mask.

Next, the second pattern 26a is formed by photolithography, for example, in a second region of the base substrate 10 including the first region so as to cover the first pattern 22a (FIG. 5C and FIG. 5D). For example, after a positive photosensitive resin film is formed over the base substrate 10, the photosensitive resin film is exposed and developed using a photomask having a mask pattern 44 as illustrated in FIG. 6B, for example, to form the second pattern 26a. In the mask pattern 44 illustrated in FIG. 6B, the center of a light shielding portion 44a corresponding to the formation region of the second pattern 26a is disposed so as to coincide with the center of the pixel region.

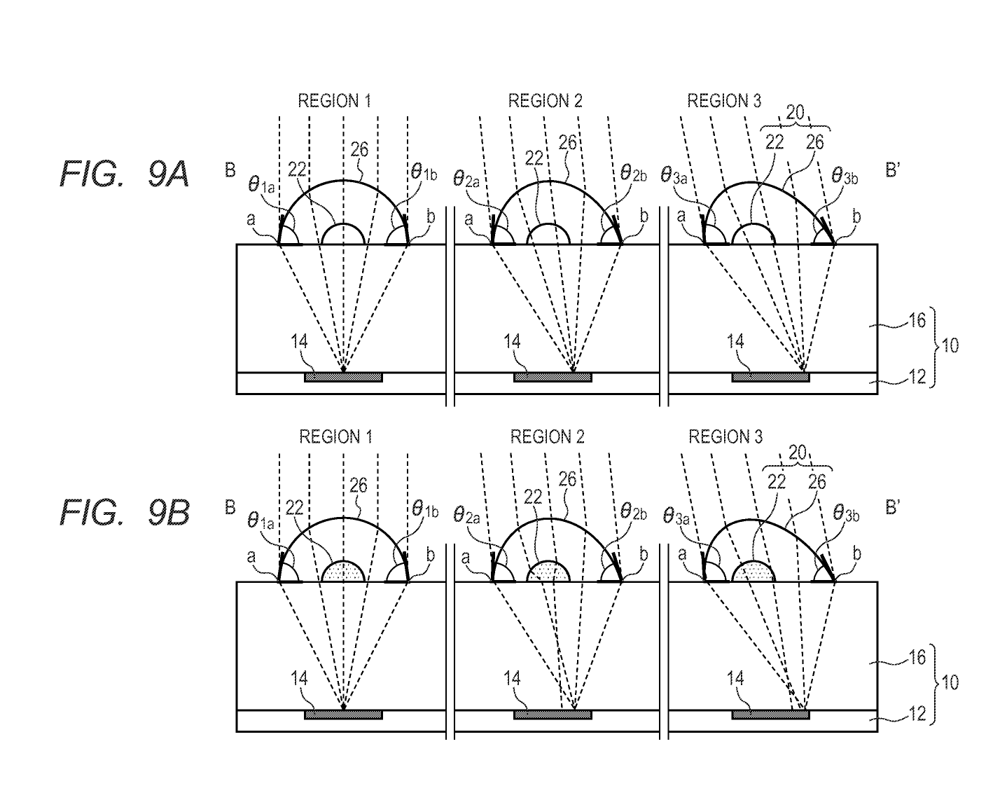

Thus, the position of center of gravity of the second pattern 26a in a plan view is disposed at a position different from the position of the center of gravity of the first pattern 22a in a plan view. To put it another way, the position of the center of gravity of the graphic form of the second pattern 26a orthographically projected on the base substrate 10 is different from the position of the center of gravity of the graphic form of the first pattern 22a orthographically projected on the base substrate 10. The amount of offset and the direction of offset between the position of the center of gravity of the first pattern 22a and the position of the center of gravity of the second pattern 26a are selected appropriately according to the shape of the microlens 20 to be formed. Since the amount in which the second pattern 26a is offset relative to the first pattern 22a varies according to the constituent material of the second pattern 26a, the heat treatment conditions to be described later, etc., the amount should be selected appropriately according to these parameters. To form a microlens array having a plurality of types of differently shaped microlenses 20, the amount of offset of the position of the center of gravity of the second pattern 26a relative to the position of the center of gravity of the first pattern 22a should be set for each microlens 20, for example, as illustrated in FIG. 9A.

To form the second pattern 26a, a negative photosensitive resin material may be used. It is not absolutely necessary to use photolithography to form the second pattern 26a. For example, the second pattern 26a may be formed by such a method as drips a resin material onto the first pattern 22a by an inkjet method. The first pattern 22a and the second pattern 26a may be composed of the same material or different materials.

Next, heat treatment is performed to liquefy the second pattern 26a. The liquefied second pattern 26a deforms under acting forces to be described below, and is shaped into an aspherical shape. Then, heat treatment is continued, and the second pattern 26a cures as is in that shape.

The treatment for liquefying the second pattern 26a is not limited to heat treatment. More specifically, other than the method of applying heat, a method of placing the second pattern 26a under a low pressure is also conceivable. To take advantage of the features of the present invention, there should be a certain time over which at least a part of the second pattern 26a reaches a liquid phase according to the phase change characteristics. As long as the first pattern 22a does not mix with the second pattern 26a, these patterns may reach a liquid phase at the same time. However, if the first pattern 22a liquefies while the second pattern 26a is liquefying and the second pattern 26a and the first pattern 22a get mixed, the unevenness of the base is substantially lost. As a result, one of the features of the present invention, the effect of stress based on Archimedes' principle, cannot be obtained. It is therefore desirable that the materials and treatment conditions of the first pattern 22a and the second pattern 26a are adjusted so that these patterns do not get mixed while the second pattern 26a is liquefying.

To stably mass-produce the microlens 20 using the manufacturing method according to the present embodiment, it is important to suppress the amount of change in shape of the second pattern 26a within a certain limit. To this end, it is desirable to reduce variation in viscosity of the second pattern 26a upon liquefaction. More specifically, it is desirable to optimize the conditions for liquefying the second pattern 26a so that the second pattern 26a does not have excessive fluidity upon liquefaction of the second pattern 26a. It is also desirable to standardize the time taken from formation to liquefaction of the second pattern 26a.

Thus, the aspherical microlens 20 including the first part 22 formed of the first pattern 22a and the second part 26 formed of the second pattern 26a is manufactured (FIG. 5E and FIG. 5F). If a pattern is melted on a base which is not flat as in the case where the second pattern 26a is formed over the base substrate 10 on which a convex portion has been formed by the first pattern 22a, deformation of the pattern occurs as follows due to actions based on Archimedes' principle.

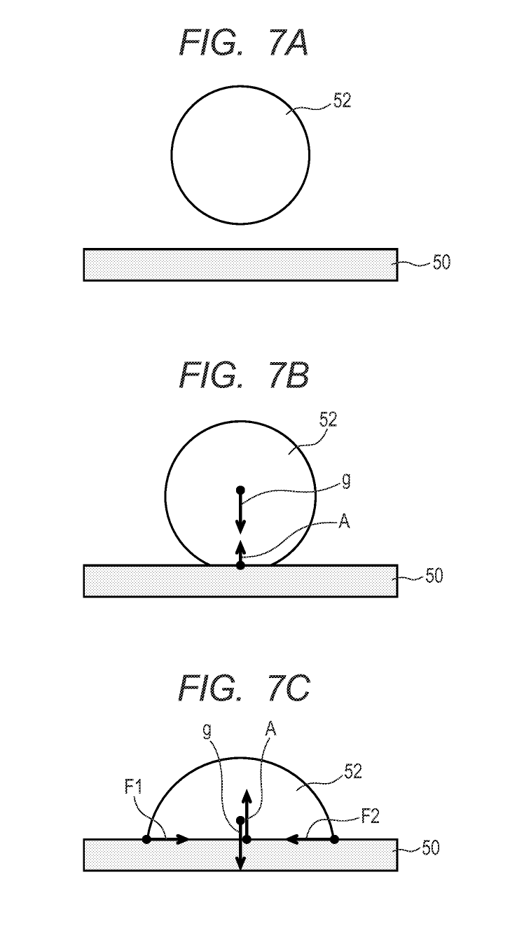

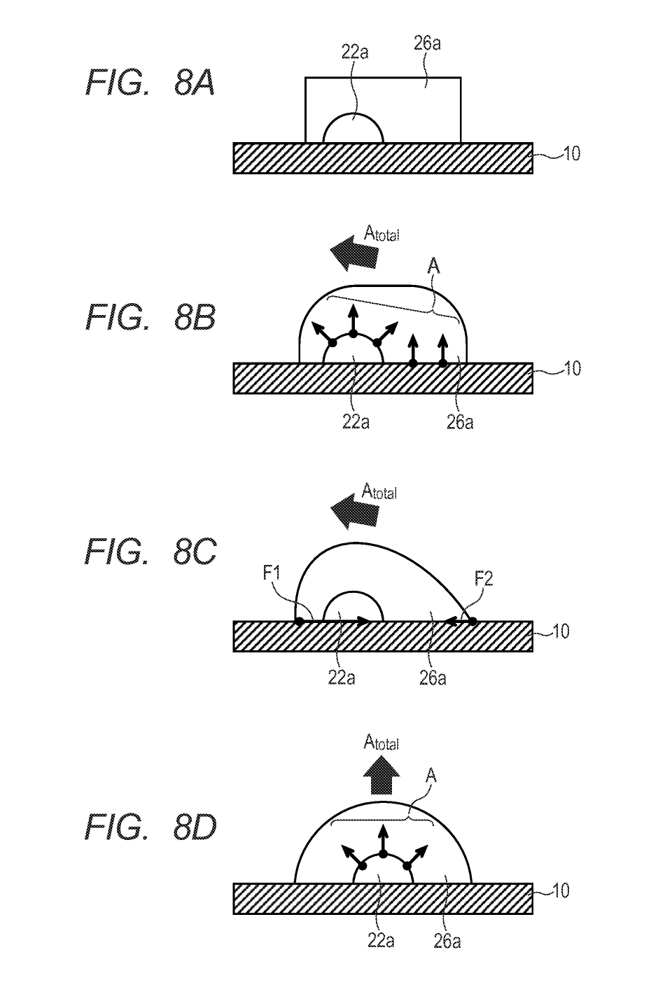

Here, deformation of the pattern due to actions based on Archimedes' principle will be described using FIG. 7A to FIG. 8D. FIG. 7A to FIG. 7C are views illustrating acting forces on a fluid and resulting changes in shape, and FIG. 8A to FIG. 8D are views illustrating changes in shape of the pattern in the method of manufacturing the microlens according to the present embodiment. Archimedes' principle is a law of physics discovered by Archimedes, and states that a force acting on a body in a fluid is equal to the weight of the fluid that the body displaces. This is expressed by the following formula:

A=ρgV (2)

Here, ρ represents the density of the fluid, g represents the gravitational acceleration, and V represents the volume of the fluid. This principle is also at work when a resin material is reflowed through heat treatment. If it is assumed that no external force (nor the gravity) acts on a liquid 52, only a gas-liquid surface tension corresponding to an internal force acts, so that the liquid 52 assumes a spherical shape as illustrated in FIG. 7A. The direction of vector of the surface tension at this point is tangential to the liquid surface. To avoid complicating the figure, the surface tension is not illustrated in FIG. 7A.

Suppose that external forces act in this state. First, the gravity g acts on the liquid 52 and causes the liquid 52 to land on a ground 50. Then, a liquid-solid surface tension occurs, and under the gravity g, a lower part of the liquid 52 starts to be distorted (FIG. 7B). The liquid-solid surface tension is not illustrated in FIG. 7B. The portion of distortion due to the ground 50 corresponds to the portion displaced in Archimedes' principle. Thus, a stress A based on the formula (2) acts on the liquid 52. When the distortion further proceeds from this state, friction forces F1, F2 start to act additionally on the liquid 52 which is spreading on the ground 50, and eventually stop the liquid 52 from spreading. This state is illustrated in FIG. 7C, which is a stable state where the acting forces are in balance.

FIG. 8A corresponds to a state after formation of the second pattern 26a, that is, to the steps illustrated in FIG. 5C and FIG. 5D. The first pattern 22a is formed on the base substrate 10, and a convex portion is formed by the first pattern 22a on the base on which the second pattern 26a is formed. Here, the first pattern 22a is covered with the second pattern 26a. The position of the center of gravity of the second pattern 26a is disposed so as to be offset toward the right side from the position of the center of gravity of the first pattern 22a.

FIG. 8B represents a state where the second pattern 26a has liquefied as a result of heat treatment and is becoming round due to a gas-liquid surface tension. In this state, acting forces (gas-liquid surface tension, liquid-solid surface tension, gravity, stress based on Archimedes' principle, liquid friction force, etc.) similar to those described in FIG. 7A to FIG. 7C are acting. However, to avoid complicating the figures, not all of the acting forces are described in FIG. 8B.

First, the liquid of the second pattern 26a becomes spherical due to the gas-liquid surface tension, while a lower part of the liquid is distorted from the spherical shape due to the gravity. Moreover, the convex shape formed on the base causes an acting force based on the portion that the body displaces in Archimedes' principle to act on the liquid. Due to the asymmetry with respect to the convex shape of the base, the acting force based on Archimedes' principle act unevenly on the left and right sides, so that a stress Aₜₒₜₐₗ acting on the second pattern 26a has a slightly upward, leftward vector as illustrated in FIG. 8B. Here, asymmetry means that of a shape in a certain cross-section. That is, asymmetry means that the position of the first pattern 22a is asymmetrical with respect to an axis passing through the center of the second pattern 26a in the base substrate 10 and parallel to the normal direction of the base substrate 10.

FIG. 8C represents a final state in which the acting forces on the liquid are in balance. One reason why the liquid assumes such an asymmetrical shape is that the liquid is under the stress Aₜₒₜₐₗ based on Archimedes' principle which acts in the leftward direction in the FIG. 8C. Another reason is that a dynamic liquid friction force acts on the liquid while the liquid is trying to move under the stress Aₜₒₜₐₗ. The dynamic liquid friction force is, for example, an external force applied to the liquid while the liquid is flowing on a solid inclined surface, and acts in the opposite direction to the forward direction of the liquid. As a result, while a forward contact angle θₐ becomes large due to the large liquid friction force F1 on the left side of FIG. 8C corresponding to the forward portion of the liquid, a backward contact angle θ_{b} becomes small due to the small liquid friction force F2 on the right side of FIG. 8C corresponding to the backward portion of the liquid. Thus, the state in which all the forces including the dynamic liquid friction forces are in balance is reached when the liquid has an aspherical shape as illustrated in FIG. 8C. The vector of the stress Aₜₒₜₐₗ in FIG. 8B and FIG. 8C is directed slightly upward. Accordingly, the apex of the second pattern 26a rises slightly as the liquefied resin material moves.

For comparison, FIG. 8D illustrates changes in shape of the second pattern 26a when the position of the center of gravity of the first pattern 22a and the position of the center of gravity of the second pattern 26a coincide with each other. As illustrated, when the convex shape (first pattern 22a) of the base is located at the center of the second pattern 26a, the stress based on Archimedes' principle acts in left-right symmetry, so that, even if the liquefied resin material moves, it does not assume an asymmetrical shape. However, compared with the case where the base substrate 10 is flat, the stress Aₜₒₜₐₗ based on Archimedes' principle is larger in the upward direction by the amount of the convex shape (first pattern 22a), so that a taller microlens 20 is formed. This technique may be used where not an asymmetrical microlens 20 but a simply taller microlens 20 is required.

In contrast to the first method illustrated above as an aspherical microlens manufacturing method which requires close calculations of melting points, viscosities, etc. of a plurality of materials, the manufacturing method of the present embodiment requires only controlling heat treatment of one material. Moreover, it is not necessary to laminate one pattern on another half-dry pattern, which makes lamination patterning easy to perform. The method of manufacturing the microlens according to the present embodiment is superior to the first method in that it is easier to produce an aspherical microlens.

While the above-described second method requires area division, the manufacturing method of the present embodiment does not require area division since the positional relation between the first pattern 22a and the second pattern 26a can be arbitrarily set through the mask patterns on the photomask. Therefore, according to the method of manufacturing the microlens according to the present embodiment, it is possible to manufacture a microlens array without involving area division which would deteriorate the image quality.

The refractive index (or the material) of the first part 22 formed of the first pattern 22a and the refractive index (or the material) of the second part 26 formed of the second pattern 26a may be the same or different from each other. If the refractive index of the first part 22 is higher than the refractive index of the second part 26, the light collection capability becomes higher, so that the microlens can be used as one disposed in a peripheral pixel part. On the other hand, if the refractive indexes of the first part 22 and the second part 26 are the same, the interface between the first part 22 and the second part 26 is only slightly visible, and the light path does not change at the interface. Therefore, as with the microlens array illustrated in FIG. 3B, a light path can be obtained which focuses light at a position corresponding to oblique incident light varying with the distance from the center (region 1) of the imaging region 32 (see FIG. 9A).

A difference from the microlens illustrated in FIG. 3B is that there is an interface between the first part 22 and the second part 26 despite the same refractive indexes of these parts. If there is an interface, total reflection of light may occur at this interface. In such cases, a sensitivity enhancing effect can be expected if a light path distance d of light passing through the second part 26 (when there is a plurality of light paths, the distance of a light path with the highest light intensity) is adjusted to such a distance that an effect of preventing reflection of wavelengths of visible light can be obtained. The condition for obtaining the reflection preventing effect is expressed by the following formula (3), where m is an integer larger than zero, λ is the wavelength of light to be prevented from reflecting (typically, visible light having a wavelength of 550 nm is used), and n is the refractive index of the first part 22 and the second part 26:

d=(2m+1)×λ/(4×n) (3)

That is, the second part 26 may function as an anti-reflection film. To suppress reflection of light at the interface between the first part 22 and the second part 26, the anti-reflection film 24 may be provided between the first part 22 and the second part 26 as illustrated in FIG. 1C. To suppress reflection at the surface of the microlens 20, the anti-reflection film 28 may be provided on the surface of the second part 26 as illustrated in FIG. 1C. The anti-reflection films 24, 28 may have a single-layer structure or a laminated structure. For example, the material of the anti-reflection film 28 can be a material having a refractive index between the refractive index of air (n=1) and the refractive index of the microlens (e.g., n≈1.6), and having a small extinction coefficient, and a film thickness of approximately 100 nm is suitable for visible light. For example, it is conceivable to form the anti-reflection film 28 from a silicon oxide film (n≈1.4), approximately 100 nm in film thickness, deposited by a low-temperature plasma CVD apparatus.

If the first part 22 and the second part 26 have different refractive indexes, the path of light passing through the microlens 20 can be changed according to the relation between these refractive indexes, which offers an option to form the first part 22 and the second part 26 from materials having different refractive indexes depending on the purpose. For example, if the first part 22 is formed of a material having a higher refractive index than the second part 26, the light path changes in a direction, in which more light is collected, at the interface between the first part 22 and the second part 26 as in the example illustrated in FIG. 9B. In this case, the incident light is refracted not only by the surface of the second part 26 but also by the interface between the first part 22 and the second part 26, so that the focus scatters. However, it is a scatter toward the center of the pixel region where the photodiode 14 is located, and therefore a color mixture suppressing effect can be expected. Since light no longer causing color mixture enters the pixel it originally should, a further sensitivity enhancing effect can also be obtained compared with the case where the first part 22 and the second part 26 have the same refractive index.

While FIG. 9B illustrates the case where the first part 22 is formed of a material having a higher refractive index than the second part 26, a larger enhancement of light collection capability may be expected if, conversely, the first part 22 is formed of a material having a lower refractive index than the second part 26. That is, the optimum condition of the refractive indexes of the first part 22 and the second part 26 depends on the optical design method of the pixels. To suppress reflection of light at the interface between the first part and the second part 26 or at the surface of the microlens 20, the same measures can be taken as in the case where the first part 22 and the second part 26 have the same refractive index.

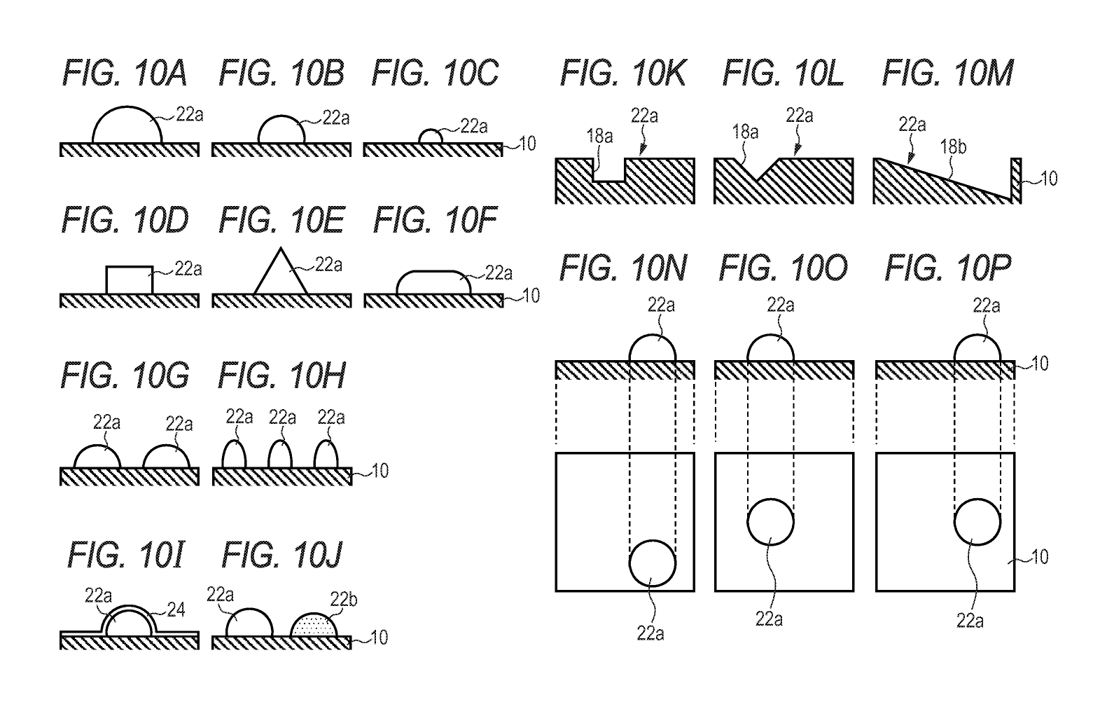

One purpose of the first pattern 22a is to form an asymmetrical base structure in a place where the second pattern 26a is to be disposed. For this purpose, there are many conceivable variations of the arrangement of the first pattern 22a, other than the arrangement in which the first pattern 22a is offset relative to the position of the center of gravity of the second pattern 26a. For example, variations of the first pattern 22a include various aspects as illustrated in FIG. 10A to FIG. 10P.

FIG. 10A, FIG. 10B and FIG. 10C illustrate modified examples of the first pattern 22a, and show that the first patterns 22a of various sizes can be used. The larger the first pattern 22a is, the larger the stress A applied from the body to the fluid is due to the larger volume V of the fluid that the body displaces in the formula (2) which expresses Archimedes' principle.

FIG. 10D, FIG. 10E and FIG. 10F illustrate modified examples of the shape of the first pattern 22a. The shape of the first pattern 22a is not limited to the spherical shape as has been described so far. For example, the first pattern 22a may be a typical solid, such as a cube, cylinder, prism, cone, pyramid, or ellipse, or may have another more complicated shape. Since the vector of the stress based on Archimedes' principle is influenced by the surface of the first pattern 22a, the shape of the microlens 20 can be controlled by appropriately selecting the shape of the surface of the first pattern 22a.

FIG. 10G and FIG. 10H illustrate other modified examples of the first pattern 22a, and show that the number of the first patterns 22a to be disposed relative to one microlens 20 can be changed variously. It is also possible to dispose a plurality of first patterns 22a in each pixel to control the shape of the microlens 20. In this case, the sizes and the shapes of the plurality of first patterns 22a to be disposed for one microlens 20 may be the same or different from one another. Moreover, the size, shape, number, arrangement, etc. of the first patterns 22a may vary among the pixels.

FIG. 10I and FIG. 10J illustrate modified examples of the manufacturing process. For example, it is not necessary to perform the step of forming the second pattern 26a directly after the step of forming the first pattern 22a, and another process step may be performed between these steps. For example, as illustrated in FIG. 10I, a step of forming the anti-reflection film 24 may be additionally performed after the step of forming the first pattern 22a and before the step of forming the second pattern 26a. Alternatively, as illustrated in FIG. 10J, the step of forming the first pattern 22a may be repeatedly performed. This option is applicable, for example, where a first pattern 22b different from the first pattern 22a in composition, size, or shape is formed.

FIG. 10K, FIG. 10L and FIG. 10M illustrate modified examples of the uneven shape to be formed in the base substrate 10. It is not absolutely necessary that the uneven shape formed in the base substrate 10 is a protrusion formed of the first pattern 22a formed on the base substrate 10, but may instead be a concave portion 18a or an inclined surface 18b. The concave portion 18a and the inclined surface 18b formed in the base substrate 10 can also be regarded to form the first pattern 22a with the base substrate 10. The stress based on Archimedes' principle acts differently when the concave portion 18a is formed in a part of the region where the second pattern 26a is to be disposed, as well as when the second pattern 26a is formed on the inclined surface 18b. For example, in these cases, the stress based on Archimedes' principle can be smaller than in the case where the second pattern 26a is formed on a flat surface. Thus, it is possible to form a microlens having a desired aspherical shape by appropriately setting the concave portion 18a or the inclined surface 18b to be formed in the base substrate 10.

FIG. 10N, FIG. 10O and FIG. 10P illustrate modified examples of the position of the first pattern 22a. In these figures, three examples are illustrated in which the first pattern 22a is disposed at different positions in a predetermined region (e.g., in one pixel region). In each figure, a cross-sectional view and a top view are shown. As the first pattern 22a is relocated, the influence of the stress based on Archimedes' principle changes, which also affects the finished shape of the second pattern 26a.

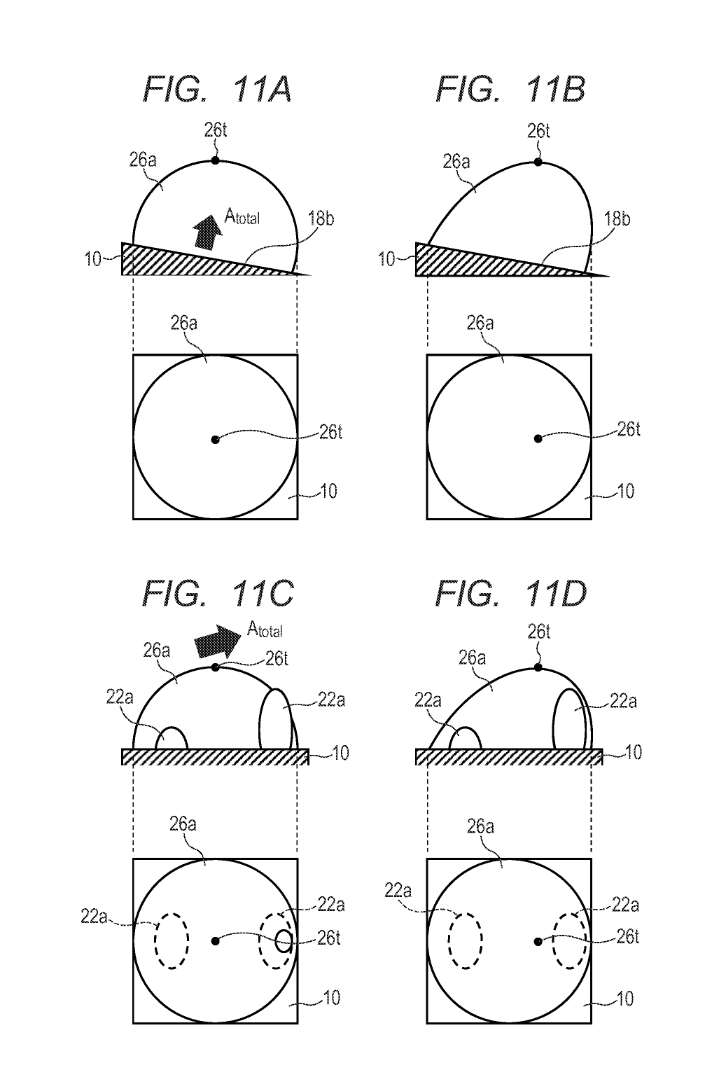

Thus, the first pattern 22a can be changed in size, shape, number, manufacturing process, unevenness, position, etc. An arbitrary pattern may be selected from these modified examples, or a plurality of patterns arbitrarily selected may be combined, to form the first pattern 22a. Formation methods of the aspherical second pattern 26a using some of the various modified examples of the first pattern 22a illustrated in FIG. 10A to FIG. 10P will be described using FIG. 11A to FIG. 11D.

FIG. 11A and FIG. 11B illustrate a method for forming the second pattern 26a on the inclined surface of the base substrate 10, and the first pattern 22a illustrated in FIG. 10M is used here. FIG. 11A illustrates a state where the second pattern 26a is disposed on the inclined surface 18b, and the second pattern 26a has liquefied as a result of heat treatment and is becoming round due to a gas-liquid surface tension. In this state, the second pattern 26a formed on the inclined surface 18b is under the stress Aₜₒₜₐₗ applied by an external force in the normal direction of the inclined surface 18b. Since this stress Aₜₒₜₐₗ contains a component in the rightward direction in FIG. 11A, deformation of the second pattern 26a proceeds so that the apex 26t shifts to the right side, and consequently the second pattern 26a is shaped into an aspherical shape (FIG. 11B).

FIG. 11C and FIG. 11D illustrate a formation method using a plurality of first patterns 22a having different shapes from one another, and the first patterns 22a illustrated in FIG. 10A to FIG. 10C, FIG. 10G and FIG. 10H are used here. Two first patterns 22a of different sizes and the second pattern 26a are disposed on the base substrate 10, and heat treatment is performed to liquefy the second pattern 26a. As a result, the second pattern 26a becomes round due to a gas-liquid surface tension as illustrated in FIG. 10C. During formation of the second pattern 26a, the first pattern 22a does not need to be completely covered with the second pattern 26a. FIG. 11C illustrates a state where a part of the first pattern 22a is not covered with the second pattern 26a. In this state, the second pattern 26a formed on the two first patterns 22a of different sizes is under a stress Aₜₒₜₐₗ containing a component in the rightward direction in FIG. 11C applied by an external force. As a result, deformation of the second pattern 26a proceeds so that the apex 26t shifts to the right side, and consequently the second pattern 26a is shaped into an aspherical shape (FIG. 11D).

The reason why it is not necessary to completely cover the first pattern 22a with the second pattern 26a is as follows. If the second pattern 26a is covered to some extent, the forces based on Archimedes' principle, i.e., the principle that a force acting on a body in a fluid is equal to the weight of the fluid that the body displaces, can be exerted sufficiently. Moreover, if covered to some extent, the first pattern 22a may be covered up automatically due to a liquid-solid surface tension between the first pattern 22a and the second pattern 26a upon liquefaction of the second pattern 26a. Of course, it is not only when there is a plurality of first patterns 22a that the first pattern 22a does not need to be completely covered with the second pattern 26a.

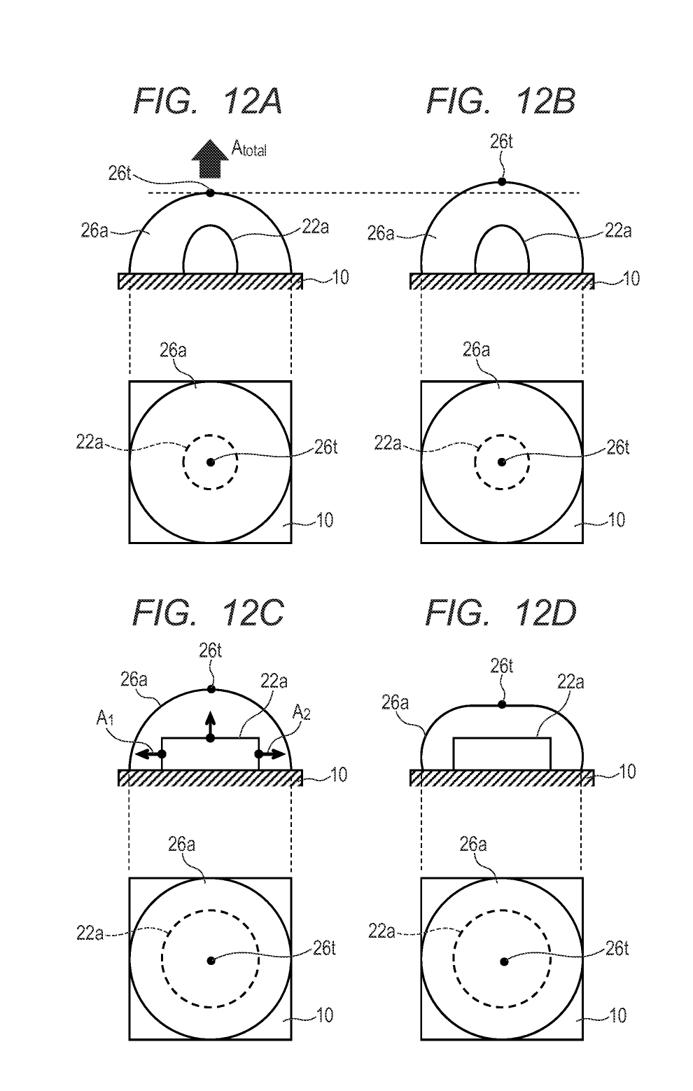

FIG. 12A to FIG. 12D illustrate other modified examples of the shape of the second pattern 26a through the first pattern 22a. Although the examples illustrated in FIG. 12A to FIG. 12D are not intended for forming an aspherical second pattern 26a, these examples are related to embodiments to be described later and therefore will be described as a supplement.

FIG. 12A and FIG. 12B are views illustrating into what shape the second pattern 26a changes when the first pattern 22a is disposed at the center of the second pattern 26a. FIG. 12A illustrates a state where the second pattern 26a has liquefied and is becoming round due to a gas-liquid surface tension, or a state immediately after formation of the second pattern 26a using a gray-tone mask. When the first pattern 22a is at the center, the stress based on Archimedes' principle acts in left-right symmetry, so that the second pattern 26a does not become asymmetrical. However, compared with the case where the base is flat, the stress Aₜₒₜₐₗ based on Archimedes' principle becomes larger in the upward direction by the amount of the first pattern 22a, so that the second pattern 26a assumes a shape similar to an ellipsoid. As a result, a microlens taller than a spherical microlens is obtained.

FIG. 12C and FIG. 12D illustrate into what shape the second pattern 26a changes when a cylindrical first pattern 22a having a relatively large width is disposed in the region where the second pattern 26a is to be disposed. In this case, as with the case of FIG. 12A and FIG. 12B, the second pattern 26a does not become asymmetrical as the stress based on Archimedes' principle acts in left-right symmetry. However, the side surface of the second pattern 26a is closer to the first pattern 22a, so that larger stresses (stresses A₁, A₂ in FIG. 12C) based on Archimedes' principle are applied to the second pattern 26a on the side surface. Thus, the second pattern 26a assumes a substantially trapezoidal shape with a round corner.

Thus, in the present embodiment, the second pattern, of which the center of gravity is located at a position different from the position of the center of gravity of the first pattern in a plan view, is formed over the first pattern, and this second pattern is reflowed to form a microlens. Therefore, according to the present embodiment, an aspherical microlens can be formed easily. Moreover, it is possible to realize a microlens having a suitable lens shape corresponding to the incident direction of incident light by appropriately setting the position of the center of gravity of the first pattern and the position of the center of gravity of the second pattern.

### Second Embodiment

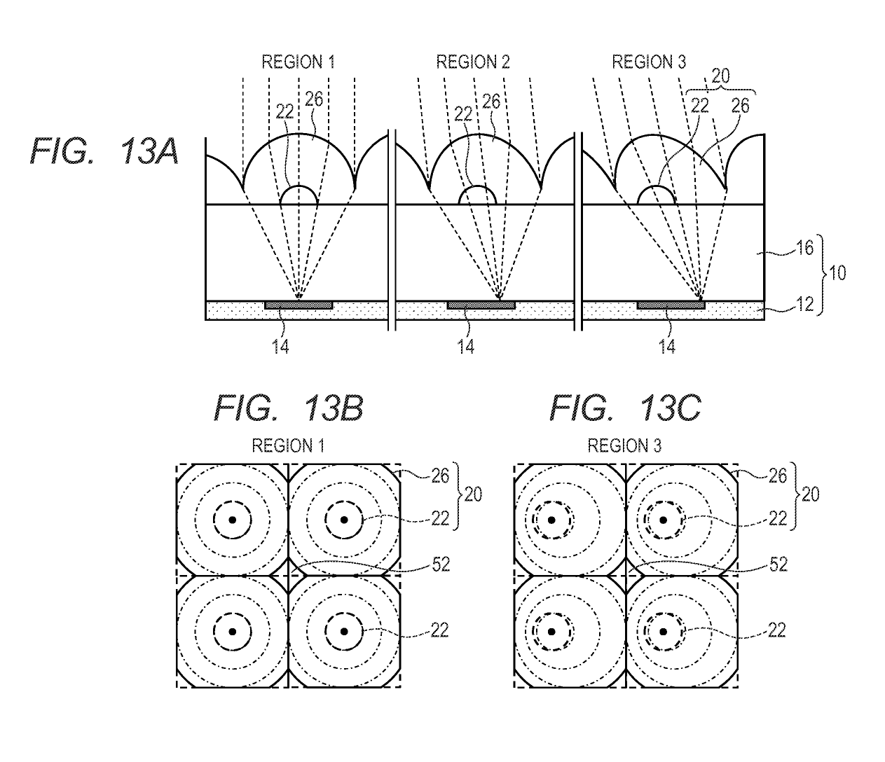

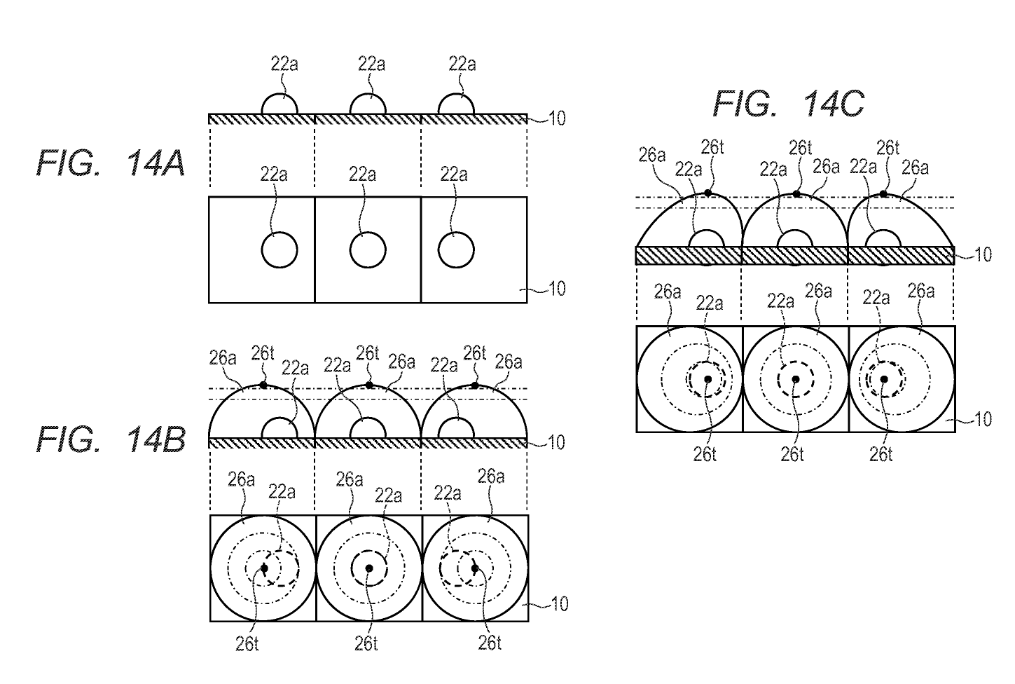

A microlens and a method of manufacturing the same according to a second embodiment of the present invention will be described using FIG. 13A to FIG. 14C. The same components as those of the microlens according to the first embodiment illustrated in FIG. 1A to FIG. 12D will be denoted by the same reference signs and description thereof will be omitted or simplified.

FIG. 13A is a cross-sectional view illustrating the structure of the microlens according to the present embodiment. FIG. 13B and FIG. 13C are plan views illustrating the structure of the microlens according to the present embodiment. FIG. 14A to FIG. 14C are cross-sectional views illustrating the method of manufacturing the microlens according to the present embodiment.

In the first embodiment, the method for manufacturing an aspherical microlens using the reflow method has been described. In the present embodiment, an example will be described in which photolithography using a gray-tone mask is utilized to form an aspherical microlens.

One technique for enhancing the sensitivity of a solid-state imaging device is to narrow the clearance between the microlenses by increasing the diameter of the microlenses. The sensitivity can be enhanced by thus increasing the area occupation ratio of the microlens in each pixel (ratio of the area over which the microlens is laid in the pixel). However, it is not possible to form a contact-type microlens array having a high area occupation ratio by the aspherical microlens manufacturing method using the reflow method as described in the first embodiment. Here, the contact-type microlens array refers to a microlens array of which each microlens has a diameter larger than the pixel size and in which adjacent microlenses are in contact with each other. The reason why this contact-type microlens array cannot be formed by the reflow method is that, if the resin material constituting the pattern is liquefied while the microlenses are in contact with each other, the microlenses fuse together through a surface tension and cannot retain the desired shapes.

One technique for manufacturing a contact-type microlens array while retaining the shapes of the individual microlenses is a method utilizing photolithography using a gray-tone mask. The gray-tone mask refers to a photomask having a mask pattern 48 as illustrated in FIG. 6D, for example, in which a large number of dots so small as not to be resolved at a light source wavelength of an exposure apparatus are disposed. By appropriately adjusting the arrangement of dots on the photomask, the degree of photoreaction of the photosensitive resin can be varied among the regions, and an arbitrary pattern, such as a spherical pattern, can be formed simply through a sequence of steps of photolithography including application, exposure and development.

Since fusion of adjacent patterns, as occurs in the reflow method, is unlikely to occur in the process utilizing photolithography using a gray-tone mask, a spherical contact-type microlens can be manufactured. Adjacent microlenses do not fuse together in the process utilizing photolithography using a gray-tone mask, because the photosensitive resin for a gray-tone mask has moderate, convenient fluidity.

The photosensitive resin for a gray-tone mask is a liquid material containing a solvent and a resin. Accordingly, the pattern after photolithography is in a state where the resin is not cured and the content of solvent is high, and lacks durability as is. It is therefore necessary to perform heat treatment as in the reflow method to volatilize the solvent and cure the resin. However, the pattern inevitably has fluidity since the pattern originally contains the liquid solvent and the base resin is the same as that used in the reflow method.

In view of this, the photosensitive resin used for photolithography using a gray-tone mask is an improved material which does not melt easily through heat treatment. This photosensitive resin is not like a resin used in the reflow method of which the component molecules are not freely movable inside the pattern, but the range of movement of the component molecules is limited. In contact-type microlenses, contact portions between microlenses contain a small amount of solvent relative to the volume, and therefore have relatively low fluidity even when thermally cured. By contrast, center portions of the microlenses contain a large amount of solvent, and therefore have relatively high fluidity.

The photosensitive resin for a gray-tone mask, which has low fluidity in the contact portions between microlenses and high fluidity in the center portions, is highly convenient for applying the present invention. This is because the microlenses can retain the lens shapes without fusing together at the contact portions, while the microlenses deform into aspherical shapes at the center portions under the stress based on Archimedes' principle. That is, if photolithography using a gray-tone mask is utilized to form the second pattern 26a, a contact-type aspherical microlens can be formed easily.

FIG. 13A to FIG. 13C are a cross-sectional view and plan views illustrating the structure of the microlens according to the present embodiment. In FIG. 13A to FIG. 13C, the region 1, the region 2 and the region 3 are the same as the region 1, the region 2 and the region 3 described in FIG. 2A to FIG. 4B. The microlenses 20 according to the present embodiment constitute a contact-type microlens array, and when seen in a cross-section, as illustrated in FIG. 13A, the surface of the second part 26 is not in contact with the surface of the interlayer insulating film 16. When seen from above, as illustrated in FIG. 13B, the second parts 26 are in contact with each other, while there is an area where the microlenses 20 are not laid, i.e., a microlens gap 52, at the position corresponding to the corners of the pixels. However, this microlens gap 52 does not have to be present. Having a large light collection area, such a contact-type microlens array can enhance the light collection efficiency.

The microlenses 20 have aspherical shapes such that differences in incident direction of incident light at different locations of the pixels can be responded to. More specifically, the microlens 20 in the region 1, which corresponds to the center part of the imaging region 32, has an almost spherical shape, while the microlenses 20 in the region 2 and the region 3 farther away from the center part have more aspherical shapes. Thus, it is possible to obtain high light collection capability by responding to oblique incident light (indicated by dashed lines in the figures) which varies with the distance from the center of the imaging region 32, while maintaining the large-area imaging region 32.

Next, the method of manufacturing the microlens according to the present embodiment will be specifically described using FIG. 14A to FIG. 14C. In each of FIG. 14A, FIG. 14B and FIG. 14C, the upper side shows a cross-sectional view and the lower side shows a top view.

First, the first pattern 22a is formed on the base substrate 10 by photolithography (FIG. 14A). Next, the second pattern 26a is formed over the base substrate 10, on which the first pattern 22a has been formed, by photolithography using a gray-tone mask (FIG. 14B). For example, the spherical second pattern 26a is formed in each pixel region using gray-tone masks each having the mask pattern 48 illustrated in FIG. 6D. Adjacent second patterns 26a are partially in contact with each other at this time.

Next, the second pattern 26a is reflowed and cured through heat treatment to shape the second pattern 26a into an aspherical shape according to the positional relation between the first pattern 22a and the second pattern 26a (FIG. 14C). At this time, since the fluidity of the photosensitive resin is low in the contact portions of the adjacent second patterns 26a and the fluidity is high in the center portions, it is possible to suppress the fluidity in the contact portions and shape the center portions into aspherical shapes.

Thus, in the present embodiment, a microlens is formed by forming the second pattern, of which the position of the center of gravity is located at a position different from the position of the center of gravity of the first pattern in a plan view, over the first pattern and reflowing the second pattern. Thus, according to the present embodiment, a microlens having an aspherical shape can be formed easily. Moreover, it is possible to realize a microlens having a suitable lens shape corresponding to the incident direction of incident light by appropriately setting the position of the center of gravity of the first pattern and the position of the center of gravity of the second pattern.

Since photolithography using a gray-tone mask is utilized to form the second pattern, a contact-type microlens array can be formed. Thus, it is possible to realize a high-sensitivity solid-state imaging device by applying this microlens array to a solid-state imaging device.

### Third Embodiment

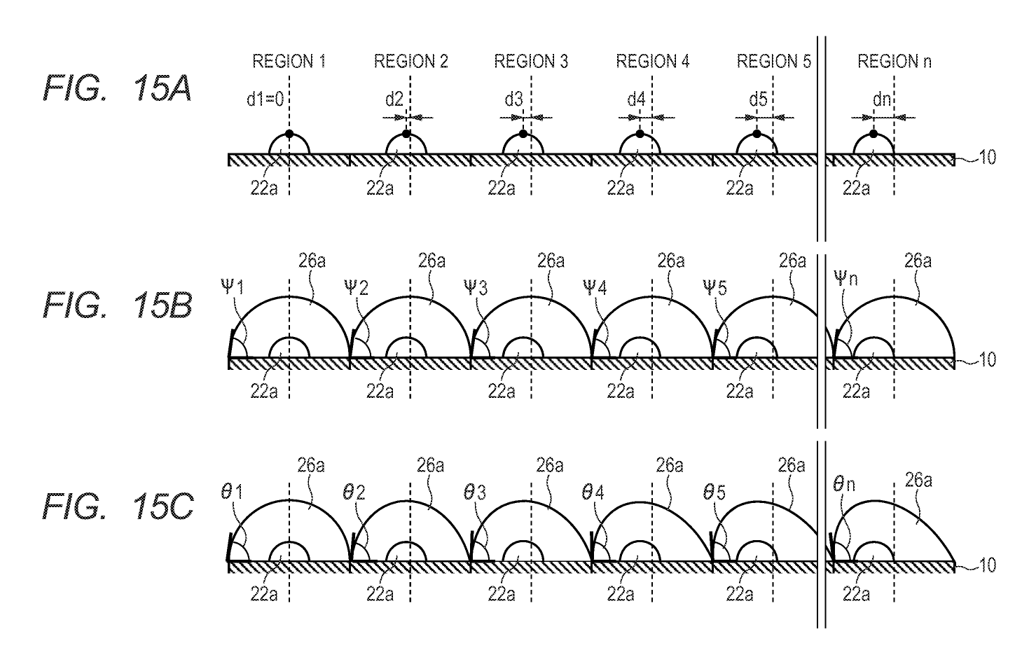

A microlens and a method of manufacturing the same according to a third embodiment of the present invention will be described using FIG. 15A to FIG. 15C. The same components as those of the microlenses according to the first and second embodiments illustrated in FIG. 1A to FIG. 14C will be denoted by the same reference signs and description thereof will be omitted or simplified. In the present embodiment, a method will be shown in which a microlens having a suitable aspherical shape is formed in each pixel in the imaging region without involving area division by the manufacturing method utilizing photolithography using a gray-tone mask.

FIG. 15A to FIG. 15C are cross-sectional views illustrating the method of manufacturing the microlens according to the present embodiment, and more particularly, are cross-sectional views along the straight line extending from the center of the imaging region 32 toward the outer periphery (corresponding to the line B-B′ of FIG. 2A). In FIG. 15A to FIG. 15C, n pixels are arrayed from the center of the imaging region 32 to the outer periphery, and the regions are sequentially numbered as the region 1, the region 2, . . . , the region n from the pixel region on the center side. The center of the imaging region 32 in this specification means a part where light enters from a direction closest to the vertical direction (parallel to the normal direction of the base substrate 10) in the imaging region 32, and the center is not necessarily the physical center point of the imaging region 32. That is, the incident angle of light entering each region becomes larger, with vertical incidence being 0 degrees, in the order of the region 1, the region 2, . . . , the region n.

First, as with the first and second embodiments, the first pattern 22a is formed on the base substrate 10 (FIG. 15A). The first pattern 22a is disposed in each pixel region such that the distance d between the center of the pixel region and the center of the first pattern 22a increases continuously in the order of the region 1, the region 2, . . . , the region n. That is, when the distances d in the region 1, the region 2, the region 3, the region 4, the region 5, . . . , the region n are distances d1, d2, d3, d4, d5, . . . , dn, respectively, this can be expressed by the following relational expression:

d1<d2<d3<d4<d5< . . . <dn

Next, the second pattern 26a is formed over the base substrate 10, on which the first pattern 22a has been formed, by photolithography using a gray-tone mask (FIG. 15B). For example, the spherical second patterns 26a are formed over the pixel regions using gray-tone masks each having the mask pattern 48 as illustrated in FIG. 6D. It is not necessary to divide the imaging region 32 into a plurality of areas and vary the shape of the second pattern 26a among the areas. That is, the contact angles ψ on the center side of the imaging region 32 of the second patterns 26a formed in the regions are the same. When the contact angles ψ in the region 1, the region 2, the region 3, the region 4, the region 5, . . . , the region n are ψ1, ψ2, ψ3, ψ4, ψ5, . . . , ψn, respectively, this can be expressed by the following relational expression:

ψ1=ψ2=ψ3=ψ4=ψ5= . . . =ψn

The values of the contact angles on the outer peripheral side of the imaging region 32 of the second patterns 26a formed in the regions are also equal. The location of the second pattern 26a defines the final location of the microlens 20, and the arrangement of the second pattern 26a in the pixel region is typically the same among all the pixel regions. In one example, as illustrated in FIG. 15B, the second pattern 26a can be disposed so that the center of the second pattern 26a coincides with the center of the pixel region. In this case, when the pairs of the first pattern 22a and the second pattern 26a disposed in the regions are compared, the distance between the position of the center of gravity of the first pattern 22a in a plan view and the position of the center of gravity of the second pattern in a plan view (distance d) varies among the regions.

To clarify the relation among the contact angles ψ relative to the base substrate 10 of the microlenses disposed in the regions, the adjacent second patterns 26a are not connected with each other in FIG. 15B. When a contact-type microlens array is to be formed, the adjacent second patterns 26a are disposed in contact with each other. When a non-contact-type microlens array is to be formed, the adjacent second patterns 26a are disposed at a distance from each other. In the latter case, it is not absolutely necessary to use a gray-tone mask, and a photomask having the mask pattern 44 illustrated in FIG. 6B may be used to form the second pattern 26a in the same manner as the first embodiment.

Next, the second pattern 26a is reflowed and cured through heat treatment to shape the second pattern 26a into an aspherical shape according to the positional relation between the first pattern 22a and the second pattern 26a (FIG. 15C). That is, as the liquefied second pattern 26a deforms in a direction in which the position of the first pattern 22a is offset, the second pattern 26a is shaped into an aspherical shape varying according to the amount of positional offset of the first pattern 22a (distance d). As a result, the contact angle θ on the center side of the imaging region 32 of the second pattern 26a after heat treatment increases in the order of the region 1, the region 2, . . . , the region n. When the contact angles θ in the region 1, the region 2, the region 3, the region 4, the region 5, . . . , the region n are θ1, θ2, θ3, θ4, θ5, . . . , θn, respectively, this can be expressed by the following relational expression:

θ1<θ2<θ3<θ4<θ5< . . . <θn

Conversely, the contact angle of the second pattern 26a on the outer peripheral side of the imaging region 32 decreases in the order of the region 1, the region 2, . . . , the region n. Thus, a microlens can be manufactured which includes the first pattern 22a and the second pattern 26a and has an aspherical shape varying according to the distance from the center of the imaging region. In particular, since the method of the present embodiment does not require dividing the imaging region 32 into a plurality of areas and varying the shape of the second patterns 26a among the areas, deterioration of image quality due to area division does not occur.

As described above, in the present embodiment, the first pattern 22a is formed using the mask pattern 42 as illustrated in FIG. 6A, and the second pattern 26a is formed using the mask patterns 44 or 48 as illustrated in FIG. 6B or FIG. 6D. That is, the present embodiment is devised such that the amount of offset between the position of the center of gravity of the first pattern 22a to be formed and the position of the center of gravity of the second pattern 26a to be formed can be defined through the layout of the mask patterns on the photomask. Therefore, a microlens of a desired shape can be formed by simply performing a normal photolithography process.

However, to increase the controllability of the shape of the microlens 20, it is required to properly adjust the application film thickness of the photosensitive resin in the photolithography process for forming the first pattern 22a and the second pattern 26a. If a misalignment occurs between the first pattern 22a and the second pattern 26a, the ideal positional offsets d1 to dn fail to be realized, which makes it difficult to form microlenses of desired shapes. One conceivable measure is to perform an exposure process using the same value of the exposure alignment condition in the photolithography process for forming the first pattern 22a and in the photolithography process for forming the second pattern 26a. Variation in alignment, or at least variation attributable to the process can be thus suppressed, so that the amount of misalignment between the first pattern 22a and the second pattern 26a is reduced, and the amounts of positional offset, the distances d1 to dn, closer to ideal amounts can be realized.

Thus, in the present embodiment, a microlens is formed by forming the second pattern, of which the center of gravity is located at a position different from the position of the center of gravity of the first pattern in a plan view, on the first pattern and reflowing the second pattern. Therefore, according to the present embodiment, a microlens having an aspherical shape can be formed easily. Moreover, it is possible to realize a microlens having a suitable lens shape corresponding to the incident direction of incident light by appropriately setting the position of the center of gravity of the first pattern and the position of the center of gravity of the second pattern.

Furthermore, when a microlens array using these microlenses is applied to a solid-state imaging device, high-quality images free of image quality deterioration due to area division can be acquired, since the shapes of the microlenses are continuously varied according to the distance from the center of the imaging region.

### Fourth Embodiment

A microlens and a method of manufacturing the same according to a fourth embodiment of the present invention will be described using FIG. 15A to FIG. 15C. The same components as those of the microlenses according to the first to third embodiments illustrated in FIG. 1A to FIG. 15C will be denoted by the same reference signs and description thereof will be omitted or simplified.

In the third embodiment, the offset between the position of the center of gravity of the first pattern 22a to be formed and the position of the center of gravity of the second pattern 26a to be formed is realized through the layout of the patterns on the photomask. In the present embodiment, another technique for realizing an offset between the position of the center of gravity of the first pattern 22a to be formed and the position of the center of gravity of the second pattern 26a to be formed will be described.

The method of manufacturing the microlens according to the present embodiment realizes an offset between the center of the pixel and the center of the first pattern 22a through exposure conditions for forming the first pattern 22a. It is not necessary to give an offset for defining the distances d1 to do to the patterns on the photomask to be used. That is, the mask pattern for forming the first pattern 22a is disposed at the same position on the photomask in all the pixel regions.

However, if photolithography is performed using such a photomask, it is not possible to define the distance d in each pixel according to the distance from the center of the imaging region 32. Therefore, in the present embodiment, photolithography for forming the first pattern 22a is performed at an exposure shot magnification, one of the exposure alignment conditions, which is lower than an exposure shot magnification for forming the second pattern 26a. If the exposure shot magnification is lower, the first pattern 22a is disposed so as to be offset further toward the center of the imaging region 32 in pixels further on the outer peripheral side of the imaging region 32, so that the distance d between the center of the imaging region 32 and the center of the first pattern 22a increases in the order of the region 1, the region 2, . . . , the region n. As a result, the same layout of the first patterns 22a as in the third embodiment illustrated in FIG. 15A can be realized. The subsequent steps are the same as those of the method of manufacturing the microlens according to the third embodiment illustrated in FIG. 15B and FIG. 15C.

Thus, even when the offset between the mask pattern of the first pattern 22a and the mask pattern of the second pattern 26a is not set for each pixel, it is possible to provide an offset by changing the exposure alignment condition which is one of the process conditions. One advantage of providing an offset through the process condition instead of the mask patterns is that it is easier to carry out. For example, there is no need for time-consuming, repeated mask revision for optimizing the amount of offset between the positions of center of gravity.

Thus, in the present embodiment, the position of the center of gravity of the first pattern and the position of the center of gravity of the second pattern are continuously varied inside the imaging region by varying the exposure shot magnification for forming the first pattern and the exposure shot magnification for forming the second pattern from each other. Therefore, according to the present embodiment, it is possible to easily optimize the relation between the position of the center of gravity of the first pattern and the position of the center of gravity of the second pattern without adding any change to the photomask.

### Fifth Embodiment

A method of manufacturing the microlens according to a fifth embodiment of the present invention will be described using FIG. 15A to FIG. 15C. The same components as those of the microlenses according to the first to fourth embodiments illustrated in FIG. 1A to FIG. 15C will be denoted by the same reference signs and description thereof will be omitted or simplified.

In the preceding embodiments, separate photomasks are used as the photomask for forming the first pattern 22a and the photomask for forming the second pattern 26a. In the present embodiment, a method will be described in which the same photomask is used for forming the first pattern 22a and the second pattern 26a.

If a gray-tone mask is used for forming the first pattern 22a and the second pattern 26a, it is not absolutely necessary to use separate masks for forming these patterns. It is possible to form the first pattern 22a and the second pattern 26a using the same gray-tone mask by appropriately adjusting the process conditions, such as the application film thickness, the amount of exposure, and the exposure alignment conditions. Sharing a photomask between two steps allows a reduction of the design man-hours and the manufacturing cost of photomasks, and ultimately a reduction of the manufacturing cost of the microlens.

For example, the first pattern 22a is formed by the method described in the fourth embodiment, under the conditions that the application film thickness of the photosensitive resin is a first film thickness and the amount of exposure is a first amount of exposure. It is possible to form the first pattern 22a into a small size as illustrated in FIG. 15A by reducing the application film thickness of the photosensitive resin and increasing the amount of exposure. Moreover, it is possible to increase the distance d between the center of the pixel and the center of the first pattern 22a in the order of the region 1, the region 2, . . . , the region n by reducing the exposure shot magnification.

For subsequent formation of the second pattern 26a, the photomask used for forming the first pattern 22a is used to form the second pattern 26a. The application film thickness of the photosensitive resin is a second film thickness larger than the first film thickness, and the amount of exposure is a second amount of exposure smaller than the first amount of exposure, while the exposure shot magnification is not changed (not reduced). The photosensitive resin to be used may be the same or different between the first pattern 22a and the second pattern 26a. Thus, as illustrated in FIG. 15B, the second pattern 26a larger than the first pattern 22a can be formed over the first pattern 22a.

The subsequent steps are the same as those of the method of manufacturing the microlens according to the third embodiment illustrated in FIG. 15C. The inventor of the present application has verified that a microlens array having microlenses of which the shapes vary according to the position in the imaging region 32 could be actually manufactured by the manufacturing method described in the present embodiment.

Thus, in the present embodiment, the first pattern and the second pattern different from each other are produced by controlling the exposure alignment conditions while using the same photomask for forming the first pattern and the second pattern. Therefore, according to the present embodiment, it is possible to reduce the design man-hours and the manufacturing cost of photomasks, and ultimately to reduce the manufacturing cost of the microlens.

### Sixth Embodiment

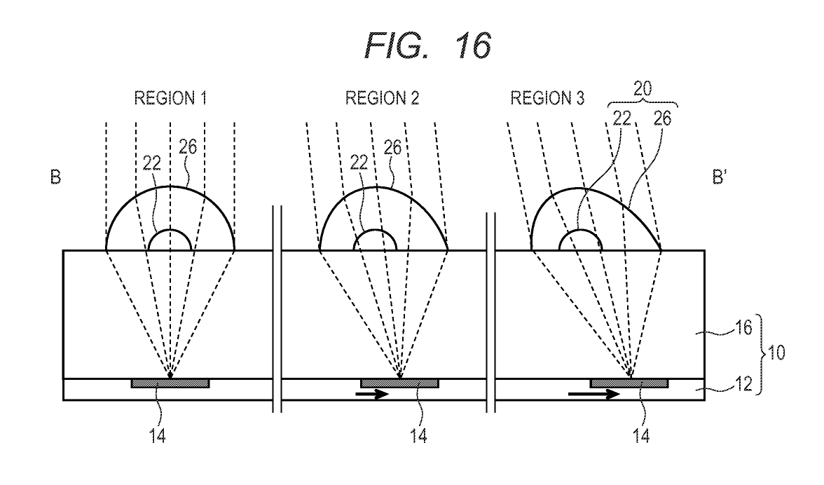

A solid-state imaging device and a method of manufacturing the same according to a sixth embodiment of the present invention will be described using FIG. 16. The same components as those of the microlenses or the solid-state imaging devices according to the first to fifth embodiments illustrated in FIG. 1A to FIG. 15C will be denoted by the same reference signs and description thereof will be omitted or simplified.

FIG. 16 is a schematic cross-sectional view illustrating the structure of the solid-state imaging device according to the present embodiment.

As described in the first to fifth embodiments, incident light of which the inclination angle increases as the distance from the center part of the imaging region 32 increases can be controlled using aspherical microlenses so that the focal plane deviation Δf becomes almost zero. On the other hand, as illustrated in FIG. 9A, for example, the focal position of light collected by the microlens is offset further toward the outside from the center of the pixel in pixels further on the outer peripheral side of the imaging region 32. When light is collected on the outside of the area of the photodiode 14, deterioration of the light collection efficiency is likely to occur.

Therefore, as illustrated in FIG. 16, the present embodiment is devised such that the relative positions of the photodiode 14 and the microlens 20 are varied according to the distance between the center of the imaging region 32 and the photodiode 14. That is, the position of the photodiode 14 relative to the microlens 20 is shifted further to the outer peripheral side of the imaging region 32 in pixels further on the outer peripheral side of the imaging region 32. Thus, it is possible to prevent light from being collected by the microlens 20 on the outside of the area of the photodiode 14 and to suppress deterioration of the light collection efficiency.

Examples of the method of manufacturing the microlens array illustrated in FIG. 16 are as follows. A first method is a method in which the location of the photodiode 14 relative to the center of the pixel is varied among the pixels according to the distance from the center of the imaging region 32. A second method is a method in which the position of the microlens layer and the position of the photodiode layer are disposed so as to be offset from each other. For example, by the same technique as the fourth embodiment, the exposure shot magnification of photolithography for forming the microlens 20 is reduced compared with the exposure shot magnification of photolithography for forming the photodiode 14. Thus, the position of the photodiode 14 relative to the microlens 20 can be shifted further toward the outer peripheral side of the imaging region 32 in pixels further on the outer peripheral side of the imaging region 32. Since it is not necessary to vary the element layout among the pixels, this method can be considered to be superior to the first method in terms of suppression of variation in characteristics among pixels and reduction of the design man-hours.

Thus, according to the present embodiment, variation in light collection efficiency depending on the location in the imaging region can be reduced, since the positional relation between the photodiode and the microlens is appropriately varied according to the distance between the center of the imaging region and the photodiode. As a result, high-quality images can be acquired.

### Seventh Embodiment

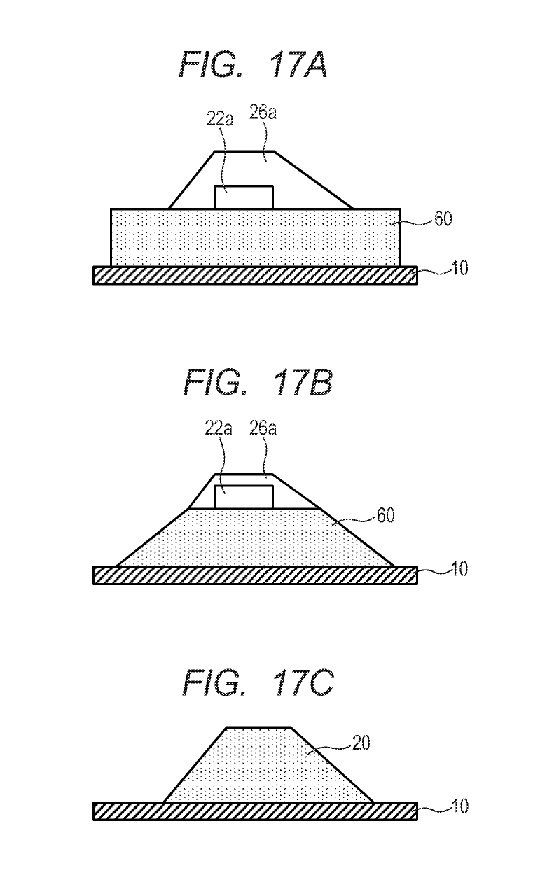

A microlens and a method of manufacturing the same according to a seventh embodiment of the present invention will be described using FIG. 17A to FIG. 17C. The same components as those of the microlenses according to the first to sixth embodiments illustrated in FIG. 1A to FIG. 16 will be denoted by the same reference signs and description thereof will be omitted or simplified. FIG. 17A to FIG. 17C are cross-sectional views illustrating the method of manufacturing the microlens according to the present embodiment.

In the first to sixth embodiments, the microlens 20 is composed of the first pattern 22a and the second pattern 26a formed by photolithography. In the present embodiment, the microlens shape may be transferred to the base by etching (etching-back) a base material using the first pattern 22a and the second pattern 26a as a mask.

In particular, when a non-contact-type microlens array is composed of the first pattern 22a and the second pattern 26a, the gap between the microlenses can be filled by transferring the microlens shapes to the base by etching-back using this microlens array as a mask. Thus, a contact-type microlens array can be formed without using a gray-tone mask.

FIG. 17A to FIG. 17C illustrate one example of the process of transferring the lens shape to the base by using etch-back method. A base film 60, to which the microlens shape is to be transferred, is formed on the base substrate 10, and the first pattern 22a and the second pattern 26a are formed on this base film 60 (FIG. 17A). The base film 60 may be a part of the interlayer insulating film 16.

Next, the base film 60 is dry-etched using the first pattern 22a and the second pattern 26a as a mask (FIG. 17B). As the etching proceeds, a film of etching substance is formed on the side wall of the second pattern 26a, gradually narrowing the clearance between microlenses. Accordingly, a contact-type microlens array can be manufactured even if the etching process is started from a non-contact-type microlens array.

Thus, the patterns of the first pattern 22a and the second pattern 26a are transferred to the base film 60 to form the microlens 20 formed of the base film 60 (FIG. 17C).

If the first pattern 22a and the second pattern 26a are formed of different materials, the etching speed can be changed from the interface between the first pattern 22a and the second pattern 26a. If actively utilized, this technique is expected to have an effect such as simplification of the manufacturing method for producing a desired shape. A further advantage of the etch-back method is a wider selection of lens materials. A high-quality microlens can be formed by selecting a transparent material for the base film 60 which is suitable as the lens material.

### Eighth Embodiment

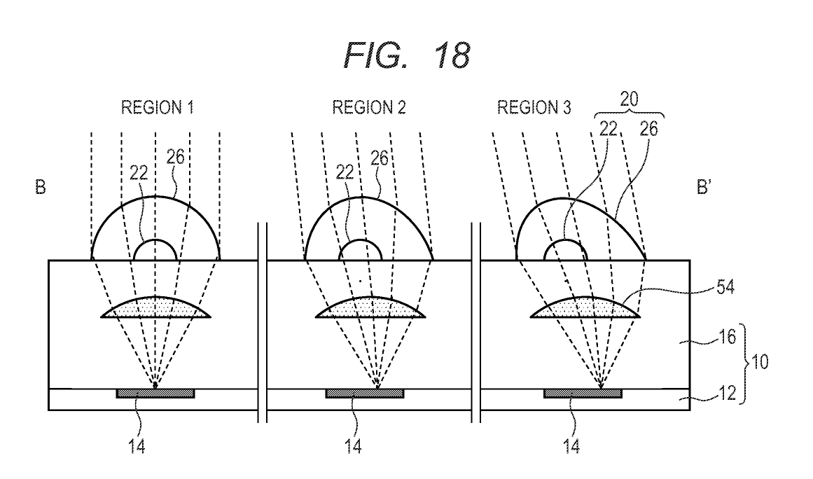

A solid-state imaging device according to an eighth embodiment of the present invention will be described using FIG. 18. The same components as those of the microlenses or the solid-state imaging devices according to the first to seventh embodiments illustrated in FIG. 1A to FIG. 17C will be denoted by the same reference signs and description thereof will be omitted or simplified.

FIG. 18 is a schematic cross-sectional view illustrating the structure of the solid-state imaging device according to the present embodiment. As illustrated in FIG. 18, the solid-state imaging device according to the present embodiment further has an inner lens 54 disposed inside the interlayer insulating film 16 between the aspherical microlens 20 and the photodiode 14. The inner lens 54 is disposed in order to further collect light that has been collected by the microlens 20 and thereby shorten the focal length. Accordingly, the inner lens 54 is composed of a material having a higher refractive index than that of the microlens 20.

As described in the first to fifth embodiments, incident light of which the inclination angle increases as the distance from the center part of the imaging region 32 increases can be controlled using aspherical microlenses so that the focal plane deviation Δf becomes almost zero. On the other hand, as the focal position is offset further toward the outside from the center of the pixel in pixels farther away from the center part of the imaging region 32, it is likely that light enters an adjacent pixel and causes color mixture.

The focal length can be shortened and the focal position can be shifted further toward the inside region of the photodiode 14 by disposing the inner lens 54 between the microlens 20 and the photodiode 14. Thus, light is prevented from entering an adjacent pixel and causing color mixture. Light no longer causing color mixture enters the photodiode 14 of the pixel it originally should, which leads to a further enhancement of the sensitivity.

Being able to shorten the focal length using the inner lens 54 has an effect that the distance to the photodiode 14 can be shortened, and is therefore also effective in application to a backside-illuminated-type solid-state imaging device.

The inner lens 54 serves to change the light path, and when the inner lens 54 is to be added, refraction of light at the inner lens 54 needs to be taken into account in the pixel design. Thus, according to the present embodiment, since the inner lens is further provided between the photodiode and the microlens, suppression of color mixture as well as enhancement of the sensitivity can be realized.

### Ninth Embodiment

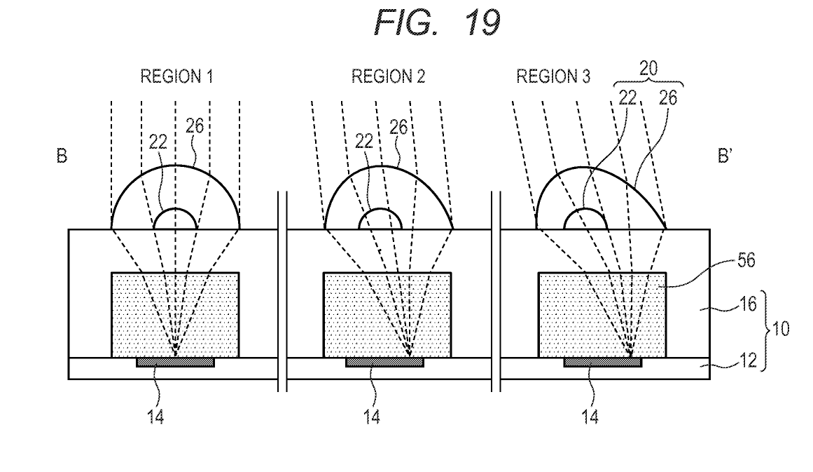

A solid-state imaging device according to a ninth embodiment of the present invention will be described using FIG. 19. The same components as those of the microlenses or the solid-state imaging devices according to the first to eighth embodiments illustrated in FIG. 1A to FIG. 18 will be denoted by the same reference signs and description thereof will be omitted or simplified.

FIG. 19 is a schematic cross-sectional view illustrating the structure of the solid-state imaging device according to the present embodiment. As illustrated in FIG. 19, the solid-state imaging device according to the present embodiment further has an optical waveguide 56 disposed inside the interlayer insulating film 16 between the aspherical microlens 20 and the photodiode 14. The optical waveguide 56 is composed of a material having a higher refractive index than the constituent material of the interlayer insulating film 16.

The optical waveguide 56 having a higher refractive index than that of the interlayer insulating film 16 has an effect of refracting light to a direction in which color mixture is prevented. Therefore, when the optical waveguide 56 is provided, as with the case where the inner lens 54 is provided as in the eighth embodiment, a color mixture reducing effect, and ultimately a sensitivity enhancing effect can be obtained.

The optical waveguide 56 serves to change the light path as with the inner lens 54, and when the optical waveguide 56 is to be added, refraction of light at the upper surface of the optical waveguide 56 needs to be taken into account in the pixel design. Thus, according to the present embodiment, since the optical waveguide having a higher refractive index is further provided inside the interlayer insulating film between the photodiode and the microlens, suppression of color mixture as well as enhancement of the sensitivity can be realized.

### Tenth Embodiment

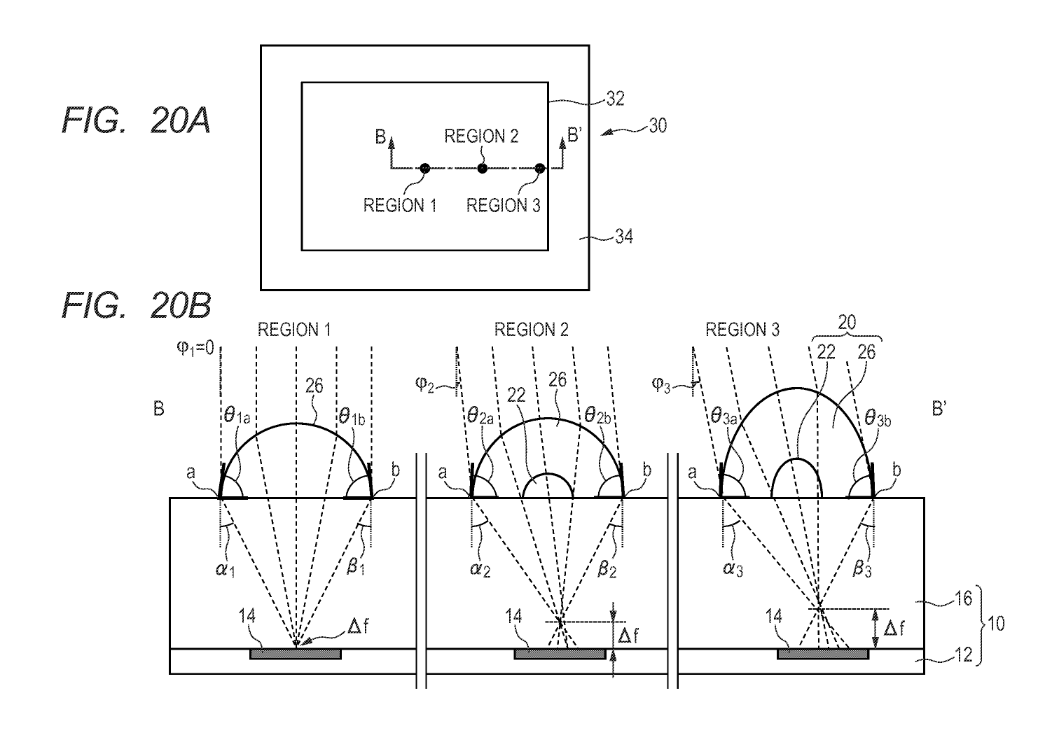

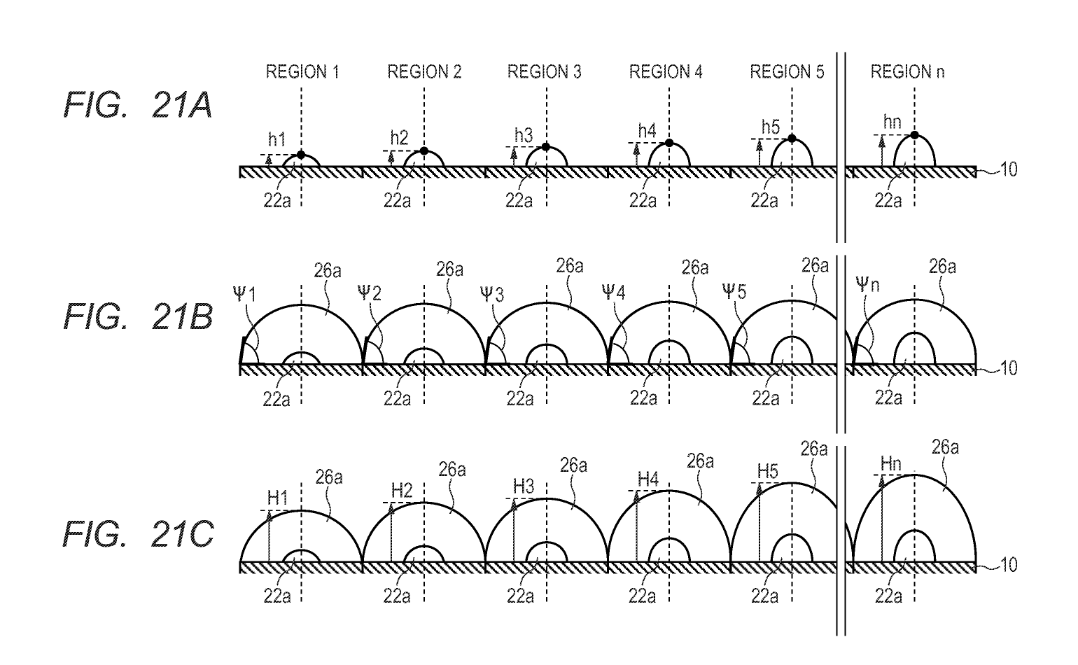

A microlens and a method of manufacturing the same according to a tenth embodiment of the present invention will be described using FIG. 20A to FIG. 21C. The same components as those of the microlenses or the solid-state imaging devices according to the first to ninth embodiments illustrated in FIG. 1A to FIG. 19 will be denoted by the same reference signs and description thereof will be omitted or simplified.

FIG. 20A is a plan view illustrating the structure of the solid-state imaging device according to the present embodiment. FIG. 20B is a cross-sectional view illustrating the structure of the solid-state imaging device according to the present embodiment. FIG. 21A to FIG. 21C are cross-sectional views illustrating the method of manufacturing the microlens according to the present embodiment.

First, the structure of the solid-state imaging device according to the present embodiment will be described using FIG. 20A and FIG. 20B. In FIG. 20A and FIG. 20B, the region 1, the region 2 and the region 3 are the same as the region 1, the region 2 and the region 3 described in FIG. 2A to FIG. 4B.

As illustrated in FIG. 20B, the solid-state imaging device according to the present embodiment has microlenses 20 of which the heights gradually increase from the center of the imaging region 32 toward the outer periphery. As will be described later, the microlenses 20 having such a structure can be realized by appropriately varying the height of the first pattern 22a according to the location. Here, the case where the refractive index of the microlens is 1.6 and the F-number of the optical system is 2.8 will be taken as an example to describe the effects of the microlens according to the present embodiment. The microlens 20 of the present embodiment has a symmetrical shape in a certain cross-section including at least the axis. However, the microlens 20 of the present embodiment may have a rotationally symmetrical spherical shape or an asymmetrical shape.

In the region 1, a spherical microlens 20 having contact angles θ₁ₐ=θ_{1b}=60 degrees is formed. In this case, light entering vertically at an incident angle φ₁=0 degrees refracts off the microlens 20 and turns into light having inclination angles α₁=β₁=approximately 27 degrees.

In the region 2, a symmetrical microlens 20 having contact angles θ₂ₐ=θ_{2b}=62 degrees is formed. For example, light entering obliquely at an incident angle φ₂=5 degrees refracts off the microlens 20 and turns into light having an inclination angle α₂=approximately 30 degrees and an inclination angle β₂=approximately 27 degrees. As a result, the focal plane shifts upward compared with the focal plane of the region 1 and the deviation rate becomes Δf=5.9%, so that the light collection capability deteriorates. However, the inclination angle β₂ (=27 degrees) is equal in value to the inclination angle β₁, and color mixture among pixels can be suppressed.

In the region 3, a symmetrical microlens 20 having contact angles θ₃ₐ=θ_{3b}=64 degrees is formed. For example, light entering obliquely at an incident angle φ₃=10 degrees refracts off the microlens 20 and turns into light having an inclination angle α₃=approximately 34 degrees and an inclination β₃=approximately 27 degrees. As a result, the focal plane shifts upward compared with the focal plane of the region 1 and the deviation rate becomes Δf=12.5%, so that the light collection capability deteriorates. However, the inclination angle β₃ (=27 degrees) is equal in value to the inclination angle β₁, and color mixture among pixels can be suppressed.

The same tendency as described above can be seen, to varying degrees, with different F-numbers of the optical system. Table 4 shows calculation results in the case where the F-number is 16.0 and the case where the F-number is 1.4, along with calculation results in the above-described case where the F-number is 2.8.

TABLE 4

| | | Lens | | | | | | |
|---|---|---|---|---|---|---|---|---|
| | | Refractive | | | | | | |
| F-number | Region n | Index | θₙₐ | θ_{nb} | φₙ | αₙ | βₙ | Δf |
| 16.0 | 1 | 1.60 | 60 | 60 | 0 | 27 | 27 | 0.0% |
| | 2 | 1.60 | 62 | 62 | 1 | 29 | 28 | 5.3% |
| | 3 | 1.60 | 64 | 64 | 2 | 31 | 29 | 10.3% |
| 2.8 | 1 | 1.60 | 60 | 60 | 0 | 27 | 27 | 0.0% |
| | 2 | 1.60 | 62 | 62 | 5 | 30 | 27 | 5.9% |
| | 3 | 1.60 | 64 | 64 | 10 | 34 | 27 | 12.5% |
| 1.4 | 1 | 1.60 | 60 | 60 | 0 | 27 | 27 | 0.0% |
| | 2 | 1.60 | 62 | 62 | 10 | 32 | 26 | 7.7% |
| | 3 | 1.60 | 64 | 64 | 20 | 38 | 26 | 18.8% |

Thus, the focal plane deviation is larger in pixels that are closer to the outer periphery of the imaging region 32. However, since the inclination angles β₁ to β₃ on the outer peripheral side of the microlenses 20 are stabilized at approximately 27 degrees, variation in amount of color mixture among the pixels in the plane of the imaging region 32 can be suppressed.

Next, the method of manufacturing the microlens according to the present embodiment will be described using FIG. 21A to FIG. 21C.

First, as with the first and second embodiments, the first pattern 22a is formed on the base substrate 10 (FIG. 21A). The area of the light shielding portion of the mask patterns is increased gradually from the center of the imaging region 32 toward the outer periphery to thereby gradually increase the height of the finished first pattern 22a from the center of the imaging region 32 toward the outer periphery.

When the heights h of the first patterns 22a in the region 1, the region 2, the region 3, the region 4, the region 5, . . . , the region n are h1, h2, h3, h4, h5, . . . , hn, respectively, this can be expressed by the following relational expression:

h1<h2<h3<h4<h5< . . . <hn

It is desirable that the first pattern 22a is thermally cured at this point so as not to mix with the second pattern 26a while the second pattern 26a is being liquefied in a later step. As illustrated in FIG. 20B, for example, it is not absolutely necessary to form the first pattern 22a in the pixels in the center part of the imaging region 32. When the pixel in the center part is the region 1, the height h1=0 in this case.

Next, the second pattern 26a is formed over the base substrate 10, on which the first pattern 22a has been formed, by photolithography using a gray-tone mask (FIG. 21B). For example, the spherical second patterns 26a are formed in the pixel regions using gray-tone masks each having the mask pattern 48 as illustrated in FIG. 6D.

In the present embodiment, the second patterns 26a of the same shape are disposed in the regions so that the centers of the second patterns 26a and the centers of the first patterns 22a respectively coincide with each other. That is, the contact angles ψ on the central side of the imaging region 32 of the second patterns 26a formed in the regions are the same. When the contact angles ψ in the region 1, the region 2, the region 3, the region 4, the region 5, . . . , the region n are contact angles ψ1, ψ2, ψ3, ψ4, ψ5, . . . , ψn, respectively, this can be expressed by the following relational expression:

ψ1=ψ2=ψ3=ψ4=ψ5= . . . =ψn

The values of the contact angles on the outer peripheral side of the imaging region 32 of the second patterns 26a formed in the regions are also equal. The shapes of the second patterns 26a formed in the regions are the same, and there is no need to divide the imaging region 32 into areas to perform photolithography using a gray-tone mask.

FIG. 21B illustrates a state where the adjacent second patterns 26a are in contact with each other on the assumption of manufacture of a contact-type microlens array. However, it is not absolutely necessary that the microlens array is of a contact type, and the adjacent second patterns 26a may be disposed at a distance from each other. In this case, there is no need to use a gray-tone mask for forming the second pattern 26a.

Next, the second pattern 26a is reflowed and cured through heat treatment. The liquefied second pattern 26a deforms in a direction, in which the height increases, according to the height h of the first pattern 22a (FIG. 21C). As described in the first embodiment using FIG. 12A and FIG. 12B, this is because the stress based on Archimedes' principle increases in the upward direction as the height h of the first pattern 22a increases. Thus, when the heights H in the region 1, the region 2, the region 3, the region 4, the region 5, . . . , the region n are heights H1, H2, H3, H4, H5, . . . , Hn, respectively, the heights H of the second patterns 26a can be expressed by the following relational expression:

H1<H2<H3<H4<H5< . . . <Hn

Accordingly, a microlens can be manufactured which includes the first pattern 22a and the second pattern 26a and of which the height varies according to the distance from the center of the imaging region 32. Thus, in the present embodiment, a microlens is formed by forming the second pattern over the first pattern, of which the height varies according to the location, and reflowing this second pattern. Therefore, according to the present embodiment, a microlens of which the height varies according to the location can be formed easily. Moreover, it is possible to realize a microlens having a suitable lens shape corresponding to the incident direction of incident light by appropriately setting the height of the first pattern.

### Eleventh Embodiment

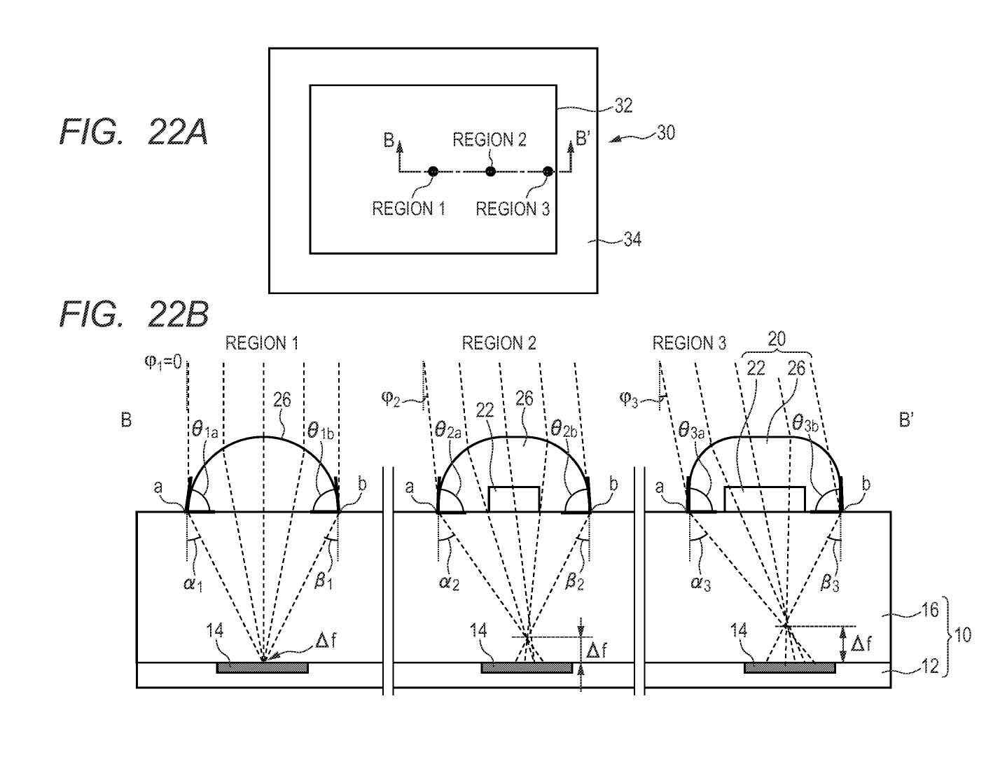

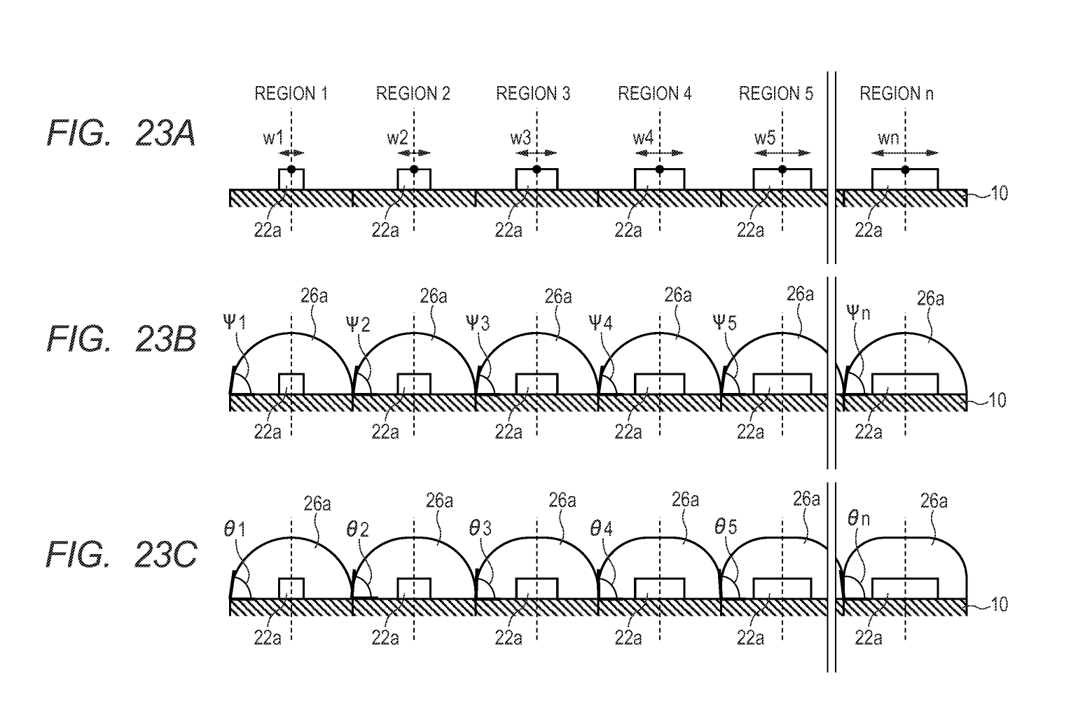

A microlens and a method of manufacturing the same according to an eleventh embodiment of the present invention will be described using FIG. 22A to FIG. 23C. The same components as those of the microlenses or the solid-state imaging devices according to the first to tenth embodiments illustrated in FIG. 1A to FIG. 21C will be denoted by the same reference signs and description thereof will be omitted or simplified.

FIG. 22A is a plan view illustrating the structure of the solid-state imaging device according to the present embodiment. FIG. 22B is a cross-sectional view illustrating the structure of the solid-state imaging device according to the present embodiment. FIG. 23A to FIG. 23C are cross-sectional views illustrating the method of manufacturing the microlens according to the present embodiment.

First, the structure of the solid-state imaging device according to the present embodiment will be described using FIG. 22A and FIG. 22B. In FIG. 22A and FIG. 22B, the region 1, the region 2 and the region 3 are the same as the region 1, the region 2 and the region 3 described in FIG. 2A to FIG. 4B.

As illustrated in FIG. 22B, the solid-state imaging device according to the present embodiment has symmetrical microlenses 20 of which the contact angles θₐ, θ_{b} increase gradually from the center of the imaging region 32 toward the outer periphery. As will be described later, the microlenses 20 having such a structure can be realized by appropriately varying the width of the first pattern 22a according to the location. The microlens 20 of the present embodiment is symmetrical in a certain cross-section including at least the axis. However, the microlens 20 of the present embodiment may have a rotationally symmetrical spherical shape or an asymmetrical shape.

Here, the case where the refractive index of the microlens is 1.6 and the F-number of the optical system is 2.8 will be taken as an example to describe the effects of the microlens according to the present embodiment.

In the region 1, a spherical microlens 20 having contact angles θ₁ₐ=θ_{1b}=60 degrees is formed. In this case, light entering vertically at an incident angle φ₁=0 degrees refracts off the microlens 20 and turns into light having inclination angles α₁=β₁=approximately 27 degrees.

In the region 2, a symmetrical microlens 20 having contact angles θ₂ₐ=θ_{2b}=61 degrees is formed. For example, light entering obliquely at an incident angle φ₂=degrees refracts off the microlens 20 and turns into light having an inclination angle α₂=approximately 30 degrees and an inclination angle β₂=approximately 27 degrees. As a result, the focal plane shifts upward compared with the focal plane of the region 1 and the deviation rate becomes Δf=4.6%, so that the light collection capability deteriorates. However, the inclination angle β₂ (=27 degrees) is equal in value to the inclination angle β₁, and color mixture among pixels can be suppressed.

In the region 3, a symmetrical microlens 20 having contact angles θ₃ₐ=θ_{3b}=65 degrees is formed. For example, light entering obliquely at an incident angle φ₃=10 degrees refracts off the microlens 20 and turns into light having an inclination angle α₃=approximately 34 degrees and an inclination angle β₃=approximately 27 degrees. As a result, the focal plane shifts further upward compared with the focal plane of the region 1, and the deviation rate becomes Δf=13.6%, so that the light collection capability deteriorates. However, the inclination angle β₃ (=27 degrees) is equal in value to the inclination angle β₁ and color mixture among pixels can be suppressed.

The same tendency as described above can be seen, to varying degrees, with different F-numbers of the optical system. Table 5 shows calculation results in the case where the F-number is 16.0 and the case where the F-number is 1.4, along with calculation results in the above-described case where the F-number is 2.8.

TABLE 5

| | | Lens | | | | | | |
|---|---|---|---|---|---|---|---|---|
| | | Refractive | | | | | | |
| F-number | Region n | Index | θₙₐ | θ_{nb} | φₙ | αₙ | βₙ | Δf |
| 16.0 | 1 | 1.60 | 60 | 60 | 0 | 27 | 27 | 0.0% |
| | 2 | 1.60 | 61 | 61 | 1 | 28 | 28 | 4.0% |
| | 3 | 1.60 | 65 | 65 | 2 | 31 | 29 | 11.5% |
| 2.8 | 1 | 1.60 | 60 | 60 | 0 | 27 | 27 | 0.0% |
| | 2 | 1.60 | 61 | 61 | 5 | 30 | 27 | 4.6% |
| | 3 | 1.60 | 65 | 65 | 10 | 34 | 27 | 13.6% |
| 1.4 | 1 | 1.60 | 60 | 60 | 0 | 27 | 27 | 0.0% |
| | 2 | 1.60 | 61 | 61 | 10 | 32 | 26 | 6.5% |
| | 3 | 1.60 | 65 | 65 | 20 | 39 | 26 | 19.7% |

Thus, while the focal plane deviation is larger in the pixels that are closer to the outer periphery of the imaging region 32, the inclination angles β₁ to β₃ on the outer peripheral side of the microlenses 20 are stabilized at approximately 27 degrees, so that variation in amount of color mixture among the pixels can be suppressed in the plane of the imaging region 32.

Next, the method of manufacturing the microlens according to the present embodiment will be described using FIG. 23A to FIG. 23C.

First, the first pattern 22a is formed on the base substrate 10 by photolithography (FIG. 23A). The diameter of the light shielding portion of the mask pattern is gradually increased from the center of the imaging region 32 toward the outer periphery, so that the cylindrical first patterns 22a are formed of which diameters w of the bottom surfaces increase from the center of the imaging region 32 toward the outer periphery. When the diameters w of the bottom surfaces in the region 1, the region 2, the region 3, the region 4, the region 5, . . . , the region n are w1, w2, w3, w4, w5, . . . , wn, respectively, this can be expressed by the following relational expression:

w1<w2<w3<w4<w5< . . . <wn

It is desirable that the first pattern 22a is thermally cured at this point so as not to mix with the second pattern 26a while the second pattern 26a is being liquefied in a later step. For example, as illustrated in FIG. 22B, it is not absolutely necessary to form the first pattern 22a in the pixels in the center part of the imaging region 32. When the pixel in the center part is the region 1, the diameter w1=0 in this case.

Next, the second pattern 26a is formed over the base substrate 10, on which the first pattern 22a has been formed, by photolithography using a gray-tone mask (FIG. 23B). For example, the spherical second patterns 26a are formed in the pixel regions using gray-tone masks each having the mask pattern 48 as illustrated in FIG. 6D.

In the present embodiment, the second patterns 26a of the same shape are disposed in the regions so that the centers of the second patterns 26a and the centers of the first patterns 22a respectively coincide with each other. That is, the contact angles ψ on the center side of the imaging region 32 of the second patterns 26a formed in the regions are the same. When the contact angles ψ in the region 1, the region 2, the region 3, the region 4, the region 5, . . . , the region n are ψ1, ψ2, ψ3, ψ4, ψ5, . . . , ψn, respectively, this can be expressed by the following relational expression:

ψ1=ψ2=ψ3=ψ4=ψ5= . . . =ψn

The values of the contact angles on the outer peripheral side of the imaging region 32 of the second patterns 26a formed in the regions are also equal. The second patterns 26a formed in the regions have the same shape, and there is no need to divide the imaging region 32 into areas to perform photolithography using a gray-tone mask.

While FIG. 23B illustrates a state where the adjacent second patterns 26a are in contact with each other on the assumption of manufacture of a contact-type microlens array, it is not absolutely necessary that the microlens array is of a contact type, and the adjacent second patterns 26a may be disposed at a distance from each other. In this case, it is not absolutely necessary to use a gray-tone mask to form the second pattern 26a.

Next, the second pattern 26a is reflowed and cured through heat treatment. The liquefied second pattern 26a deforms into a lens shape having a large width like a trapezoid according to the size of the diameter w of the bottom surface of the first pattern 22a (FIG. 23C). This is as has been described in the first embodiment using FIG. 12C and FIG. 12D. Thus, when the contact angles θ on the center side of the imaging region 32 in the region 1, the region 2, the region 3, the region 4, the region 5, . . . , the region n are contact angles θ1, θ2, θ3, θ4, θ5, . . . , θn, respectively, the contact angles θ of the second patterns 26a can be expressed by the following relational expression:

θ1<θ2<θ3<θ4<θ5< . . . <θn

The values of the contact angles on the outer peripheral side of the imaging region 32 of the second patterns 26a formed in the regions are also equal. Thus, a microlens can be manufactured which includes the first pattern 22a and the second pattern 26a and has a symmetrical shape of which the contact angle varies according to the distance from the center of the imaging region 32.

Accordingly, in the present embodiment, a microlens is formed by forming the second pattern over the first pattern of which the width varies according to the location, and reflowing this second pattern. Thus, according to the present embodiment, a microlens of which the contact angle varies according to the location can be formed easily. Moreover, it is possible to realize a microlens having a suitable lens shape corresponding to the incident direction of incident light by appropriately setting the width of the first pattern.

In the tenth and eleventh embodiments, the positional relation between the first pattern 22a and the second pattern 26a may be such that the centers of gravity coincide with each other in a plan view, or that the centers of gravity are offset from each other. Changes in shape of the first pattern 22a are not limited to the height or the width, and changes in shape that are not according to the position in the imaging region may also be adopted.

### OTHER EMBODIMENTS

The present invention is not limited to the above-described embodiments but can be modified in various ways.

For example, in the third embodiment, a common mask pattern is used for all the pixels to form the second patterns, but the mask pattern does not have to be common when a gray-tone mask is used. For example, the imaging region may be divided into a plurality of areas according to the distance from the center, and the mask pattern, i.e., the shape of the second pattern, may be varied among the areas. Since the final shape of the microlens is determined by the relation between the position of the center of gravity of the first pattern and the position of the center of gravity of the second pattern, it is not absolutely necessary that the shape of the second pattern before reflowing is the same among all the pixels.

In the third embodiment, the case has been shown where the distance between the position of the center of gravity of the first pattern and the position of the center of gravity of the second pattern is continuously varied according to the distance from the center of the imaging region. However, it is not absolutely necessary to continuously vary the distance. It is to prevent generation of borders due to an extreme change in optical characteristics of the microlens between pixels that the distance between the position of the center of gravity of the first pattern and the position of the center of gravity of the second pattern is continuously varied. As long as the change in optical characteristics does not become so large that the border becomes visible, the distance between the position of the center of gravity of the first pattern and the position of the center of gravity of the second pattern may be varied stepwise among groups of pixels.

In the fourth embodiment, the exposure shot magnification for forming the first pattern is reduced compared with the exposure shot magnification for forming the second pattern. However, the exposure shot magnification can be appropriately selected according to the shape of the microlens array to be shaped. For example, to form a microlens array having the structure illustrated in FIG. 4B, the exposure shot magnification for forming the first pattern should be increased compared with the exposure shot magnification for forming the second pattern.

In the above embodiments, the examples have been shown where the method of the present invention for forming an asymmetrical pattern with respect to at least one reference is applied to manufacture of microlenses. However, the present invention is not only applicable to manufacture of microlenses, but is also widely applicable to formation of asymmetrical, substantially ellipsoidal patterns. One example is application to the field of micro electro mechanical systems (MEMS). The tenth and eleventh embodiments are applicable not only to asymmetrical patterns with respect to one reference but also to symmetrical patterns.

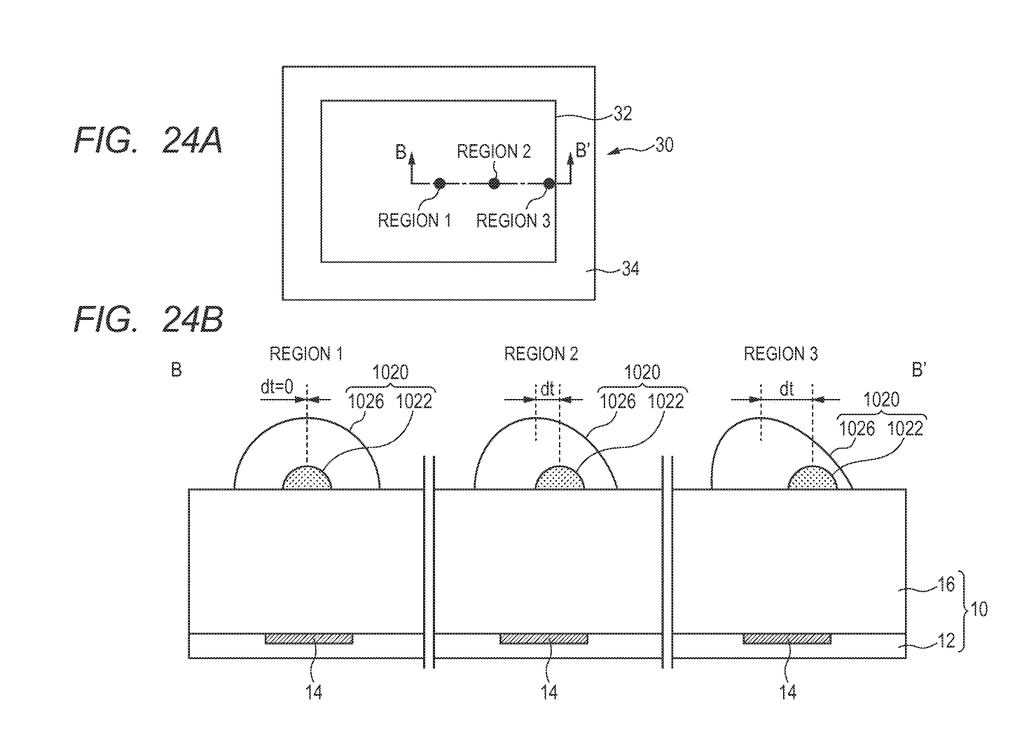

The forms illustrated in FIG. 24A and FIG. 24B are also possible. FIG. 24B is a cross-sectional view along the line B-B′ of FIG. 24A, and a microlens 1020 in FIG. 24B has a first part 1022 in contact with the base substrate 10 and a second part 1026 in contact with the base substrate 10 while covering the first part 1022. The first part 1022 and the second part 1026 function as a lens having a light collecting effect. The first part 1022 is composed of a material having a first refractive index, and the second part 1026 is composed of a material having a second refractive index lower than the first refractive index.

As illustrated in FIG. 24B, the pixel provided in the region 1 has the microlens 1020 including the spherical first part 1022 and the spherical second part 1026. An amount of offset dt between the apex of the first part 1022 and the apex of the second part 1026 is almost zero. The pixels provided in the region 2 and the region 3 have the microlenses 1020 each including the spherical first part 1022 and the rotationally asymmetrical, aspherical second part 1026. In the region 2 and the region 3, the apex of the first part 1022 is offset toward the outside of the imaging region 32 from the center of the pixel, while the apex of the second part 1026 is offset toward the center side of the imaging region 32 from the center of the pixel, and there is an offset between these apexes. The amount of offset dt between the apex of the first part 1022 and the apex of the second part 1026 is larger on the outer peripheral side of the imaging region 32. That is, the amount of offset dt between the apex of the first part 1022 and the apex of the second part 1026 in the pixel of the region 3 is larger than the amount of offset dt between the apex of the first part 1022 and the apex of the second part 1026 in the pixel of the region 2.

Of light passing through the microlens 1020, light that has passed through the second part 1026 and further passed through the first part 1022 is significantly bent, and the incident angle of the light entering the photodiode 14 is adjusted. In particular, in the pixels in the peripheral part of the imaging region 32, the incident angle of light entering the photodiode 14 is smaller. If the structure of the microlens 1020 including the first part 1022 having a higher refractive index is adopted, difference between the pixels in the center part of the imaging region 32 and the pixels in the outer peripheral part is reduced in terms of illumination area, center of gravity of light intensity, and incident angle, so that the sensitivity in the plane of the imaging region 32 is further uniformized. Thus, deterioration of the sensitivity in the pixels in the peripheral part of the imaging region 32 can be reduced.

The first part 1022 and the second part 1026 can be manufactured by appropriately using the reflow method, an area gradation exposure method, etc.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-258496, filed Dec. 22, 2014, and Japanese Patent Application No. 2015-113683, filed Jun. 4, 2015, which are hereby incorporated by reference herein in their entirety.

What is claimed is:

1. A method of manufacturing a microlens comprising:
forming a first pattern over a substrate;
forming a second pattern over the substrate with the first pattern formed on so as to cover the first pattern, a center of gravity of the second pattern being located at a position different from a position of a center of gravity of the first pattern in a plan view; and
reflowing the second pattern to shape the second pattern and form a microlens.

2. The method of manufacturing a microlens according to claim 1, wherein
in reflowing the second pattern, the second pattern having a symmetrical shape is shaped into the microlens having an aspherical shape.

3. The method of manufacturing a microlens according to claim 1, further comprising:
curing the first pattern before forming the second pattern.

4. The method of manufacturing a microlens according to claim 1, wherein
in forming the first pattern, a plurality of first patterns is formed,
in forming the second pattern,
a plurality of second patterns is formed so that each of the plurality of second patterns covers each of the plurality of first patterns, and
the plurality of second patterns is disposed so that, of a plurality of pairs of the first pattern and the second pattern covering the first pattern, at least two pairs are different from each other in a distance between the position of the center of gravity of the first pattern in a plan view and the position of the center of gravity of the second pattern in a plan view, and
in reflowing the second pattern, each of the plurality of second patterns is reflowed to form a plurality of microlenses.

5. The method of manufacturing a microlens according to claim 4, wherein
in forming the plurality of second patterns, the plurality of second patterns is disposed so that adjacent second patterns are in contact with each other.

6. The method of manufacturing a microlens according to claim 4, wherein
the plurality of microlenses is arranged in a two-dimensional array to constitute a microlens array, and
the distance between the position of the center of gravity of the first pattern and the position of the center of gravity of the second pattern in the plurality of pairs varies continuously from a center toward an outer periphery of the microlens array.

7. The method of manufacturing a microlens according to claim 4, wherein
in forming the plurality of first patterns, the plurality of first patterns is formed by photolithography using a first photomask having a plurality of first mask patterns corresponding to the plurality of first patterns, and
in forming the plurality of second patterns, the plurality of second patterns is formed, under a same exposure alignment condition as an exposure alignment condition for forming the plurality of first patterns, by photolithography using a second photomask having a plurality of second mask patterns corresponding to the plurality of second patterns, a center of gravity of each of the plurality of second mask patterns being located at a position different from a position of a center of gravity of each of the plurality of first mask patterns.

8. The method of manufacturing a microlens according to claim 4, wherein
in forming the plurality of first patterns, the plurality of first patterns is formed by photolithography using a first photomask having a plurality of first mask patterns corresponding to the plurality of first patterns, and
in forming the plurality of second patterns, the plurality of second patterns is formed, at an exposure shot magnification different from an exposure shot magnification for forming the plurality of first patterns, by photolithography using a second photomask having a plurality of second mask patterns corresponding to the plurality of second patterns, a center of gravity of each of the plurality of second mask patterns being located at a same position as a position of a center of gravity of each of the plurality of first mask patterns.

9. The method of manufacturing a microlens according to claim 8, wherein
in forming the plurality of first patterns, the first photomask is used and a photosensitive resin film having a first film thickness is exposed in a first amount of exposure, and
in forming the plurality of second patterns, the first photomask is used as the second photomask, and a photosensitive resin having a second film thickness thicker than the first film thickness is exposed in a second amount of exposure smaller than the first amount of exposure.

10. The method of manufacturing a microlens according to claim 1, further comprising:
transferring a shape of the microlens to the substrate by etching-back the substrate using the microlens as a mask.

11. A microlens provided over a substrate comprising:
a first part provided over the substrate; and
a second part which is provided over the substrate so as to cover the first part, a center of gravity of the second part being located at a position different from a position of a center of gravity of the first part in a plan view, the second part having a rotationally asymmetrical shape with respect to an axis parallel to a normal direction of the substrate.

12. The microlens according to claim 11, wherein
a light path distance of light passing through the second part of the second part is defined so as to prevent reflection at an interface between the first part and the second part.

13. The microlens according to claim 11, further comprising:
a first anti-reflection film provided between the first part and the second part.

14. The microlens according to claim 11, wherein
a refractive index of the first part and a refractive index of the second part are different from each other.

15. A solid-state imaging device comprising:
a substrate including an imaging region where a plurality of pixels including a photoelectric conversion element are arranged in a two-dimensional array; and
a microlens array for collecting light on each of the photoelectric conversion element of the plurality of pixels, the microlens array being formed of a plurality of microlenses arranged in a two-dimensional array,
each of the plurality of microlenses having a first part provided over the substrate, and a second part provided over the substrate so as to cover the first part, wherein a center of gravity of the second part is located at a position different from a position of a center of gravity of the first part in a plan view, and having a rotationally asymmetrical shape with respect to an axis parallel to a normal direction of the substrate, and
the plurality of microlenses including at least two microlenses which are different from one another in distance between the position of the center of gravity of the first part and the position of the center of gravity of the second part in a plan view.

16. The solid-state imaging device according to claim 15, wherein
a positional relation between the photoelectric conversion element and the microlens constituting one pixel varies continuously from a center toward an outer periphery of the microlens array.

17. The solid-state imaging device according to claim 15, further comprising:
a plurality of inner lenses, each of the plurality of inner lenses being provided between the photoelectric conversion element and the microlens of each of the plurality of pixels.

18. The solid-state imaging device according to claim 15, wherein
the substrate further includes an interlayer insulating film provided between the plurality of pixels and the microlens array, and
the interlayer insulating film includes
a first region having a first refractive index and
a second region having a second refractive index different from the first refractive index provided between the photoelectric conversion element and the microlens of each of the plurality of pixels.

19. A method of manufacturing a microlens array comprising:
forming a plurality of first patterns over a substrate;
forming a plurality of second patterns over the substrate with the plurality of first patterns formed on so that each of the plurality of second patterns covers each of the plurality of first patterns; and
reflowing the second patterns to shape the second patterns and form microlenses, wherein
the plurality of first patterns has different shapes from one another.
